(19) United States
(12) Patent Application Publication
(10) Pub. No.: US 2025/0006653 A1
(43) Pub. Date: Jan. 2, 2025

(54) FIDUCIALS WITH ASSOCIATED LOW-DENSITY METAL ZONES

(71) Applicant: Intel Corporation, Santa Clara, CA (US)

(72) Inventors: Omkar G. Karhade, Chandler, AZ (US); Nitin A. Deshpande, Chandler, AZ (US); Bhaskar Jyoti Krishnatreya, Hillsboro, OR (US); Francisco Maya, Portland, OR (US); Siyan Dong, Chandler, AZ (US); Alveera Gill, Hillsboro, OR (US); Tan Nguyen, Hillsboro, OR (US); Keith E. Zawadzki, Portland, OR (US)

(73) Assignee: Intel Corporation, Santa Clara, CA (US)

(21) Appl. No.: 18/346,108

(22) Filed: Jun. 30, 2023

(51) Int. Cl. H01L 23/544; H01L 23/00; H01L 25/065

(52) U.S. Cl. CPC H01L 23/544; H01L 24/33; H01L 25/0657; H01L 2223/54426; H01L 2224/3313; H01L 2225/06593; H01L 2924/1431; H01L 2924/2026

(57) ABSTRACT

An apparatus comprising an integrated circuit device comprising a fiducial area of a first layer, the fiducial area comprising a metal area and a metal free area; and a plurality of zones that are metal free in multiple layers adjacent to the first layer, wherein the zones are defined by a footprint based on the fiducial area of the first layer and a second fiducial area of a second integrated circuit device, the footprint comprising multiple slits.

### BACKGROUND

Hybrid bonding interconnect is a packaging technology involving electrical and mechanical connection between two semiconductor devices. In order to bond two semiconductor devices together, surfaces of the devices are brought together under applied pressure and/or at elevated temperature. Hybrid bonding interconnect enables the integration of heterogeneous semiconductor devices (e.g., using different technology nodes or materials) onto a single wafer or package, utilizing various bonding methodologies, such as dielectric-to-dielectric bonding and metal-to-metal bonding.

The devices involved in hybrid bond process may include one or more fiducials (e.g., a structure used for alignment and positioning purposes during manufacturing and assembly processes). The relative positioning of the fiducials may be detected and used to provide an indication of whether the devices were aligned properly.

### BRIEF DESCRIPTION OF THE DRAWINGS

FIGS. 1A-1B and 2A-2B illustrate example integrated circuit devices comprising fiducials.

FIG. 3 provides a schematic illustration of a cross-sectional view of an example integrated circuit device.

FIG. 4 illustrates example fiducial patterns that form a footprint for low-density metal zones.

FIG. 5 illustrates a cross section of first and second integrated circuit devices.

FIG. 6 illustrates a cross section of first and second integrated circuit devices.

FIG. 7 illustrates additional example fiducial patterns.

FIG. 8 illustrates additional example fiducial patterns.

FIG. 9 illustrates additional example fiducial patterns.

FIG. 10 illustrates a process for forming low-density metal zones and fiducials.

FIG. 11 is a top view of a wafer and dies that may include fiducials with associated low-density metal zones.

FIG. 12 is a cross-sectional side view of an integrated circuit device that may include fiducials with associated low-density metal zones.

FIGS. 13A-13D are simplified perspective views of example planar, FinFET, gate-all-around, and stacked gate-all-around transistors.

FIG. 14 is a cross-sectional side view of an integrated circuit device assembly that may include fiducials with associated low-density metal zones.

FIG. 15 is a block diagram of an example electrical device that may include fiducials with associated low-density metal zones.

FIG. 16 illustrates additional example fiducial patterns.

FIG. 17 illustrates a cross section of first and second integrated circuit devices.

FIGS. 18-21 illustrate additional example fiducial patterns.

### DETAILED DESCRIPTION

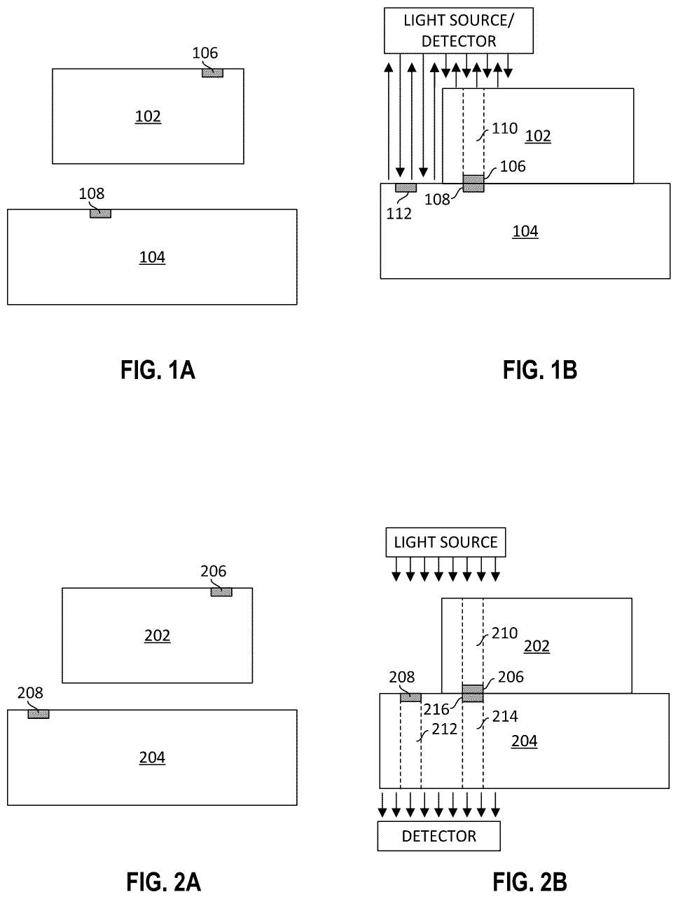

FIGS. 1A-1B illustrate example integrated circuit devices 102 and 104 comprising fiducials 106 and 108. An integrated circuit device may represent any suitable apparatus comprising semiconductor devices, interlayer dielectrics, and metal interconnects, such as a die or a wafer comprising a plurality of dies. The devices may be bonded together as shown in FIG. 1B using a hybrid bonding process.

In some embodiments, hybrid bonding may be performed on a wafer-level (wafer-to-wafer bonding), i.e., individual wafers being hybrid bonded before they are separated into dies. In other embodiments, hybrid bonding may be performed on a die-level (die-to-die bonding), i.e., the dies of individual wafers being hybrid bonded after the wafers have been separated into dies. In yet other embodiments, dies of a wafer may be separated into dies and then hybrid bonded to a wafer before the latter is separated into dies (die-to-wafer bonding).

In various embodiments, devices 102 and 104 may be bonded to one another using a bonding material. In some embodiments, the devices may be heterogenous. For example, they may be fabricated by different manufacturers, using different materials, and/or different manufacturing techniques. For each device, the terms “bottom face” or “back side” of the device may refer to the back of the device, e.g., bottom of the support structure of a given device, while the terms “top face” or “front side” of the device may refer to the opposing other face. When the top face of the first IC device is bonded to the top face of the second IC device (as depicted in FIG. 1B), the devices are described as bonded “face-to-face” (f2f). When the top face of the first IC device is bonded to the bottom face of the second IC device or the bottom face of the first IC device is bonded to the top face of the second IC device, the devices are described as bonded “face-to-back” (f2b). When the bottom face of the first IC device is bonded to the bottom face of the second IC device, the devices are described as bonded “back-to-back” (b2b). The embodiments described herein may be used with any of these bonding types.

In some embodiments, bonding of the faces of the first and second IC devices may be performed using insulator-insulator bonding, e.g., oxide-oxide bonding, where an insulating material of the first IC device is bonded to an insulating material of the second IC device. In some embodiments, a bonding material may be present in between the faces of the first and second IC devices that are bonded together. The bonding material may be applied to one or both faces of the first and second IC devices that should be bonded and then the first and second IC devices are put together, possibly while applying a suitable pressure and heating up the assembly to a suitable temperature. In some embodiments, the bonding process typically takes place at room temperature. The IC devices are subsequently treated at a higher temperature (e.g., in the range or 250 to 450 degrees Celsius to form covalent bonds between the dielectrics and the metal-to-metal bonds between the interconnecting metals. In some embodiments, the bonding material may comprise an adhesive material and/or an etch-stop material. In some embodiments, no bonding material is used, but a bonding interface may still result from the bonding of the first and second IC devices to one another. In some embodiments, other types of bonding may be applied (e.g., metal-metal bonding or other suitable bonding). After bonding, conductive contacts (e.g., bumps) on the first device may be electrically connected to corresponding conductive contacts on the second device.

In hybrid bonding, bump pitches may be much tighter than pitches used in other forms of bonding, e.g., in solder based bonding or C4 bonding. For example, the pitches may be smaller than 10 microns (or even smaller than 1 micron in some cases). Accordingly, alignment accuracy between the dies is critical to ensure proper connectivity between conductive contacts of a first IC device (e.g., die) and conductive contacts of a second IC device (e.g., die).

As depicted in FIG. 1A, fiducials 106, 108, and 112 are formed on or near the front sides of the respective devices. In order to facilitate bonding with high accuracy, the hybrid bonding process may utilize fiducials on the IC devices. Fiducials may also be used during a post bonding inspection process step to measure bond overlay alignment accuracy. The alignment accuracy information may be fed back to the hybrid bonding equipment so that the equipment may make any appropriate adjustments to improve alignment accuracy for other devices as well as fed forward to indicate whether a device is defective based on the bonding results.

In various implementations, alignment metrology uses infrared (IR) light to pass through the device (e.g., through silicon and an inter-layer dielectric (ILD) stack of a die) and compare bonded fiducials in either a reflective or a transmissive mode. FIG. 1B illustrates a reflective mode in which a light source provides IR light which passes down through devices 102 and 104. A portion of this light will be reflected by metal present in devices 102 and 104 (e.g., metal present in fiducials 106, 108, and 112) back to a detector. The detector may use the detected light to identify the position of fiducial 106 on the top device 102 and the position(s) of the fiducials 108 and/or 112 on the base device 104 and determine alignment errors based on a comparison of the positions.

In the embodiment of FIG. 1B, the devices may be considered aligned when fiducial 106 is aligned over fiducial 108 and/or when fiducial 106 is offset from fiducial 112 (e.g., in the x and/or y direction by the proper distances). Thus, in various embodiments, the fiducials (e.g., 106 and 112) can be offset from each other (e.g., in the x and/or y direction) and the alignment is based on how much the position differences between the fiducials vary from the desired offset. FIGS. 2A-2B illustrate other example semiconductor devices 202 and 204 comprising fiducials 206 and 208 that are offset from each other (as well as fiducial 216 that is aligned with fiducial 206). FIG. 2B also illustrates another mode (a transmissive mode) of alignment metrology in which IR light from a light source passes through both devices and is detected on the other side of the devices. The light may pass through metal-free areas and may be at least partially blocked by metallization.

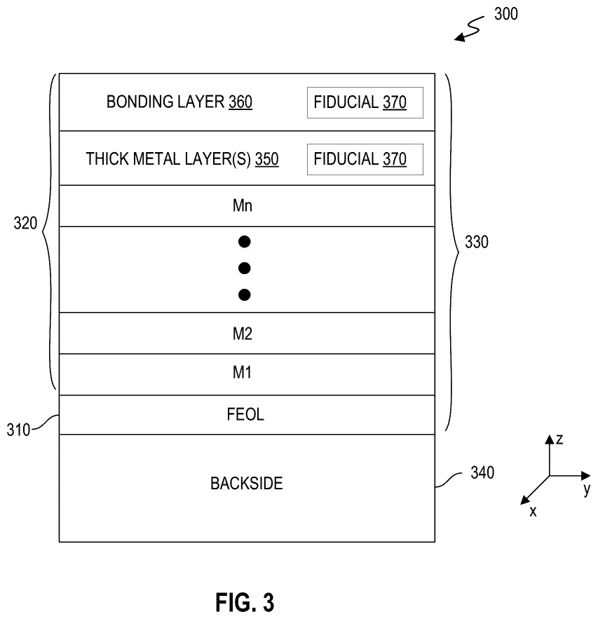

FIG. 3 provides a schematic illustration of a cross-sectional view of an example integrated circuit device (e.g., a die) 300, according to some embodiments of the present disclosure.

Embodiments described herein may include front-end-of-line (FEOL) semiconductor processing and structures. FEOL may be a first portion of IC fabrication where the individual devices (e.g., transistors, capacitors, resistors, etc.) are patterned in the semiconductor substrate or layer. FEOL generally covers everything up to (but not including) the deposition of metal interconnect layers. Following the last FEOL operation, the result is typically a wafer with isolated transistors (e.g., without any wires).

Embodiments described herein may also include back end of line (BEOL) semiconductor processing and structures. BEOL is the second portion of IC fabrication where the individual devices (e.g., transistors, capacitors, resistors, etc.) are interconnected with wiring on the wafer, e.g., the metallization layer or layers. BEOL may include contacts, insulating layers (dielectrics), metal levels, and bonding sites for chip-to-package connections. In the BEOL part of the fabrication stage contacts (pads), interconnect wires, vias and dielectric structures are formed.

Embodiments described herein may be applicable to FEOL processing and structures, BEOL processing and structures, or both FEOL and BEOL processing and structures. In particular, although an exemplary processing scheme may be illustrated using a FEOL processing scenario, such approaches may also be applicable to BEOL processing. Likewise, although an exemplary processing scheme may be illustrated using a BEOL processing scenario, such approaches may also be applicable to FEOL processing.

As shown in FIG. 3, the IC device 300 may include a front side 330 comprising a FEOL portion 310 that includes various logic layers, circuits, and devices to drive and control a logic IC. These circuits and devices may be configured for any number of functions, such as logic or compute transistors, input/output (I/O) transistors, access or switching transistors, and/or radio frequency (RF) transistors, to name a few examples. According to some embodiments, in addition to these devices and circuits, FEOL portion 310 may include, for example, one or more other layers or structures associated with the semiconductor devices and circuits. For example, the FEOL portion 310 can also include a substrate and one or more dielectric layers that surround active and/or conductive portions of the devices and circuits. The FEOL portion may also include one or more conductive contacts that provide electrical contact to transistor elements such as gate structures, drain regions, or source regions. The FEOL portion may also include local interconnect (e.g., vias or lines) that connect contacts to interconnect features within the BEOL portion 320.

The front side 330 of the IC device 300 also includes a BEOL portion 320 including various metal interconnect layers (e.g., metal 1 through metal n, where n is any suitable integer) and thick metal layer(s) 350 comprising one or more metal layers having one or more thickness that are greater than the thicknesses of the lower metal layers (e.g., metal 1 through metal n). Various metal layers of the BEOL portion 320 may be used to interconnect the various inputs and outputs of the FEOL portion 310.

Generally speaking, each of the metal interconnect layers of the BEOL portion 320, e.g., each of the layers M1-Mn and thick metal layer(s) 350 (sometimes referred to as giant metal layers) shown in FIG. 3, may include a via portion and a trench/interconnect portion. Typically, the trench portion of a metal layer is above the via portion, but, in other embodiments, a trench portion may be provided below a via portion of any given metal layer of the BEOL portion 320. The trench portion of a metal layer may be configured for transferring signals and power along metal lines (also sometimes referred to as “trenches”) extending in the x-y plane (e.g., in the x or y directions), while the via portion of a metal layer may be configured for transferring signals and power through metal vias extending in the z-direction, e.g., to any of the adjacent metal layers above or below. Accordingly, vias connect metal structures (e.g., metal lines or vias) from one metal layer to metal structures of an adjacent metal layer. While referred to as “metal” layers, various layers of the BEOL portion 320, e.g., layers M1-Mn or thick metal layer(s) 350 shown in FIG. 3, may include certain patterns of conductive metals, e.g., copper (Cu), aluminum (Al), Tungsten (W), or metal alloys, or more generally, patterns of an electrically conductive material, formed in an insulating medium such as an interlayer dielectric (ILD). The insulating medium may include any suitable ILD materials such as silicon oxide, silicon nitride, silicon carbon nitride, silicon carbide, aluminum oxide, and/or silicon oxynitride. In various embodiments, the insulating medium may have sufficient transparency for IR light (in some embodiments, the IR light may have a wavelength of 1-2 microns) to pass through to facilitate detection of fiducials. In various embodiments, any one or more of these layers may additionally include active devices (e.g., transistors, diodes) and/or passive devices (e.g., capacitors, resistors, inductors).

In various embodiments, a bonding layer 360 may be formed at the top surface of the IC device 300. The bonding layer 360 may include, e.g., various electrical contacts (e.g., bumps, pads, etc.) that may be electrically connected to corresponding electrical contacts of another IC device in a hybrid bonding process. In some embodiments, the bonding layer 360 may also include one or more dielectric materials to create the bonding between the IC devices (e.g., the dielectric material may be placed in between the electrical contacts).

In various embodiments, a fiducial 370 may be placed at or near a surface (e.g., a front side) of an IC device. For example, a fiducial 370 may be placed in the bonding layer 360. Additionally or alternatively, a fiducial 370 may be placed in one or more of the thick metal layer(s) 350. In some embodiments, the same fiducial 370 may be formed in the bonding layer 360 as well as in a thick metal layer 350. In some embodiments, the same fiducial 370 may be formed in multiple layers of the thick metal layer(s) 350. In other embodiments, a fiducial 370 may be formed in another suitable layer near the bonding layer 360 (e.g., one of the other upper metal layers). In some embodiments, a portion of a fiducial may be formed in one layer and another portion of the fiducial may be formed in another layer.

The IC device 300 may also include a back side 340. For example, the back side 340 may formed on the opposite side of a wafer from the front side 330. In various embodiments, the back side 340 may include any suitable elements to assist operation of the IC device 300. For example, the back side 340 may include various metal layers to deliver power to logic of the FEOL portion 310. In some embodiments, transistors or other circuit elements may be formed on the back side 340 of the IC device 300.

In various embodiments, fiducial 370 may include a pattern formed by a metal, such as copper, aluminum, tantalum, or other type of metal (e.g., used in a routing layer). The patterning in the fiducial may have any suitable dimensions. The patterning may be thick enough to reflect and/or block IR light. For example, the patterning may be between 0.025 microns and 5 microns thick. Typical fiducials used in hybrid bonding may be on the order of 30×30 microns to 120×120 microns. If the stack of layers in a device has an interconnect grid of metal underneath a standard fiducial, then the IR light may be blocked by the metal of the grid. Accordingly, a metal free zone in the fiducial footprint underneath the fiducial is preferred for alignment metrology so as not to distort the detection of the fiducial (as used herein a footprint may refer to an area in the x-y plane that can be extended up and/or down in the z-direction). In FIGS. 1 and 2, metal free zones (or other low-density metal zones) are bounded by dashed lines and fiducials and are depicted as 110, 112, 210, 212, and 214. In some embodiments, the metal free zone (or other low-density metal zone) may persist through the full stack on the base device 104, 204 for transmissive mode (e.g., as shown by 212 and 214) or only through thicker metals for reflective mode (e.g., as shown by 112).

In various embodiments, the area underneath the footprint of the fiducial 370 (which may include the layers underneath the fiducial and may be referred to herein as a “zone”) need not be completely metal free in order for sufficient IR light to pass through the layers for alignment metrology purposes. In some embodiments, the area underneath the footprint may be a “low-density metal zone”, such that the density of the metal through the zone is low enough that sufficient IR light passes through for detection of the pattern of the fiducial (and thus could include a no metal zone or a zone with sufficiently low aggregate metal density in the layers). For example, in some low-density metal zones, one or more of the thinnest metal layers (e.g., the lowest metal layers) may be allowed to have a first threshold percentage of metal density (e.g., 20%, 30%, etc.), one or more of the next thinnest metal layers may be allowed to have a second threshold percentage (e.g., 10%, 15%, etc.) of metal density which is lower than the first threshold percentage, and so on (e.g., other thresholds may be employed for other metal layers), while some of the thicker layers (e.g., thick metal layer(s) 350 and/or other higher metal layers underneath the layer(s) with the fiducial) may be required to be metal free within the footprint of the fiducial.

Large low-density metal (e.g., metal free) zones may be problematic. For example, such zones having a large size corresponding to the size of a fiducial (e.g., in the range of 30×30 microns up to 120×120 microns) may create issues during fabrication process steps (e.g., chemical mechanical planarization (CMP) and plating) due to resulting metal density variations across the device.

In various embodiments of the present disclosure, low-density metal zones are present in an IC device in narrow slits within the footprint of a fiducial area as defined by the size and geometry of the fiducials. In various embodiments, the fiducial area may be defined by the expected outer perimeter of metal in a pair of corresponding fiducials (e.g., a fiducial on a top IC device and a fiducial on a base IC device) when perfectly aligned. Within the fiducial area, there may be a plurality of blank slits in the combined fiducial pattern (where the combined fiducial pattern refers to the combined pattern when one fiducial of the pair is overlaid on the other fiducial). The blank slits may correspond to no-metal areas in the layers in which the fiducials are formed. The footprint of the blank slits may define a low-density metal zone on the first IC device through which IR light may pass. In some embodiments, the footprint of the blank slits may also define a low-density metal zone through at least a portion of the second IC device.

Accordingly, in some embodiments, a large metal-free zone under the entire footprint of the fiducial area is avoided. Various embodiments may provide technical advantages, such as a reduced fiducial footprint or reduced process (e.g., CMP topography, plating) issues.

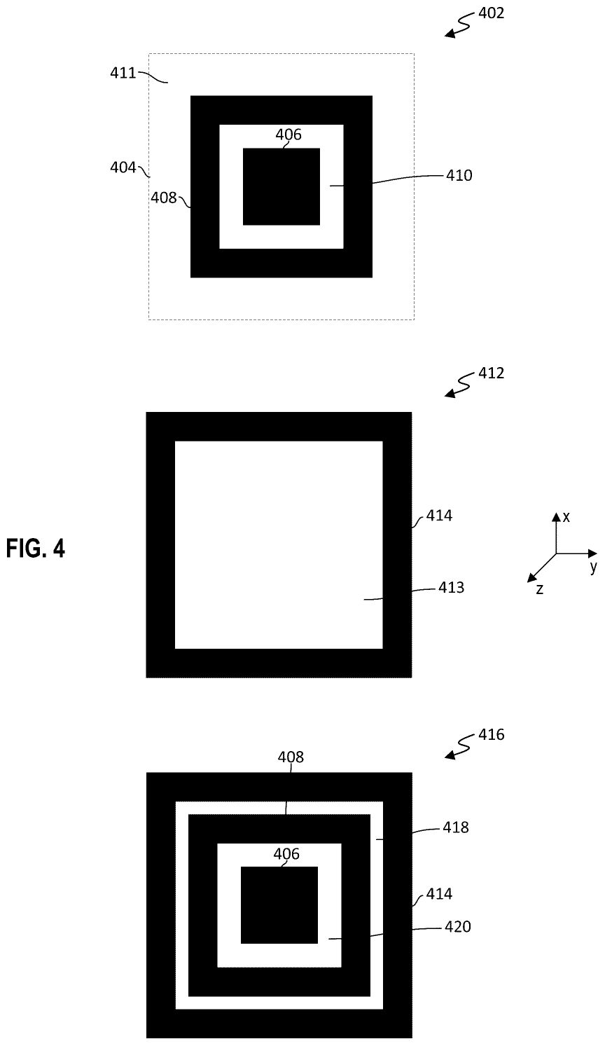

FIG. 4 illustrates fiducial patterns 402, 412, and 416. The patterns are shown as top-down views spanning across the x and y directions. Pattern 402 may be implemented on a first IC device (e.g., a top die) and pattern 412 may be implemented on a second IC device (e.g., a base die), or vice versa. In some embodiments, the fiducial represented by pattern 402 may be formed on multiple layers of the first IC device (e.g., the fiducial may be duplicated on multiple layers, such as a bonding layer and a thick metal layer or on two thick metal layers) or may be formed across multiple layers (e.g., a portion of the fiducial may be formed on one layer and another portion of the fiducial may be formed on another layer). The fiducial represented by pattern 412 may be similarly formed on the second integrated circuit device.

Pattern 416 represents pattern 402 overlaid on pattern 412 (and thus may be representative of the pattern that may be detected responsive to application of IR light during alignment metrology when the first IC device and the second IC device are perfectly aligned as the detected IR light passing through the blank areas will be distinguishable from light that is blocked or reflected by metal areas).

The fiducial patterns are bounded by a fiducial footprint 404 which in some examples may be defined by the outer perimeter of the outermost metal of the pair of fiducials when aligned (e.g., the outer perimeter of metal area 414 in this case). In some embodiments, the fiducial footprint 404 may be expanded beyond the outer perimeter of the outermost metal of the pair of fiducials, e.g., to provide an expanded low-density metal zone within the footprint to allow detection of one or more edges of the outermost metal when the outermost metal is on the fiducial of the base die.

The fiducial pattern 402 of the first IC device includes a first metal area 406 (comprising a solid square), a first blank area 410, a second metal area 408 (comprising a square shaped ring), and a blank area 411. The second metal area 408 may be defined by an outer perimeter having a square shape and an inner perimeter having a square shape with metal formed in the area between the outer perimeter and inner perimeter. Herein, the term ring may be used to refer to such a structure defined by an inner perimeter and an outer perimeter with the same shape, regardless of the shape. The blank areas 410 and 411 are also depicted as square shaped rings.

The fiducial pattern 412 of the second IC device includes a blank area 413 shaped as a solid square and a metal area 414 (comprising a square shaped ring). The combined fiducial pattern 416 includes metal area 406, metal area 408, and metal area 414. The combined fiducial pattern 416 also includes blank areas 418 and 420 (with each blank area having the shape of a square shaped ring).

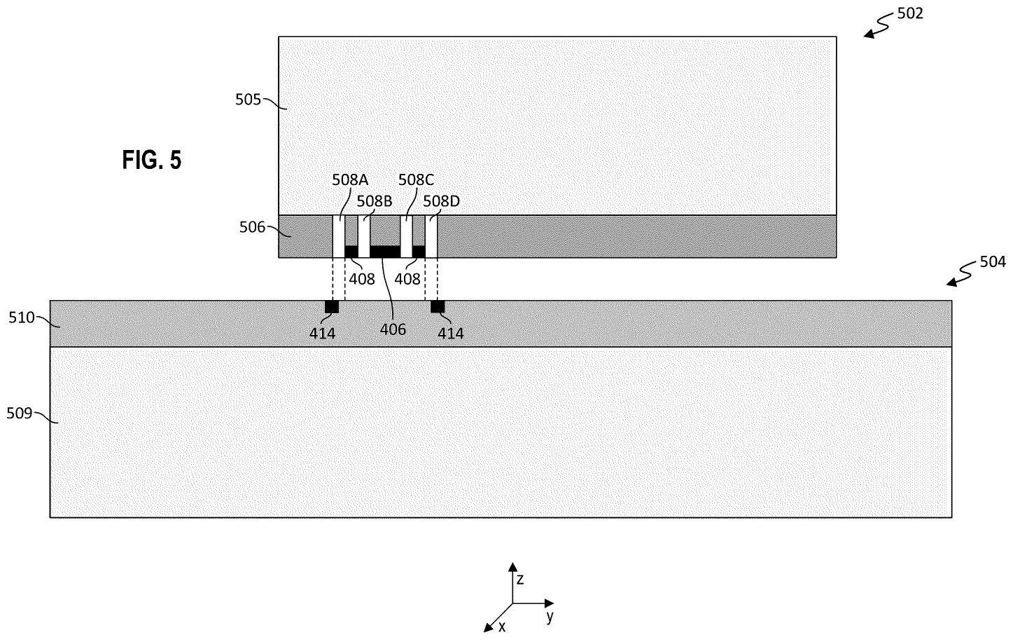

In various embodiments, the blank areas within the footprint of the combined fiducial 416 may include a plurality of slits. For example, blank area 418 may include four slits (with each slit corresponding to a side of the square shaped ring). Each slit of the blank area 418 may define a low-density metal zone that extends through other layers of the first IC device (e.g., multiple adjacent metal interconnect layers underneath and/or adjacent to a layer of the fiducial), as illustrated in FIG. 5. Indeed, the blank areas of the combined pattern may form a lateral cross section (e.g., in the x and y directions) or footprint through which the low-density metal zones may extend through the IC device in the z-direction. In various embodiments, the low-density metal zones may have a larger footprint than that shown by the blank areas of the combined fiducial 416. For example, in order to ensure that the inner edge of the metal area 414 can be detected, the footprint for the low-density metal zone may occupy the area shown by 418 as well as a portion of the area shown as being occupied by metal area 414. This concept is illustrated more clearly in FIG. 5.

FIG. 5 illustrates a cross section of a first IC device 502 and a second IC device 504. The first IC device 502 comprises a first portion 505 and a second portion 506. The first portion 505 may comprise one or more materials (e.g., silicon) that allow the passage of IR light during fiducial detection. In some embodiments, the first portion 505 may represent an FEOL portion or portion thereof. The second portion 506 may comprise one or more materials (e.g., metals) that reflect and/or block IR light applied during fiducial detection. In order to ensure that sufficient IR light passes through in the appropriate zones during fiducial detection, low-density metal zones 508 corresponding to the slits of the blank areas of combined pattern 416 may be defined in the second portion 506 of the first IC device 502.

In the embodiment depicted, the fiducial pattern 402 may be implemented in a bonding layer of IC device 502 which may be on the bottom of the device (e.g., after the device is manufactured it may be flipped over prior to bonding). A cross section (e.g., taken through the center of the fiducial) is shown in FIG. 5. As depicted, the metal area 406 and left and right portions of metal area 408 are shown. Low-density metal zones 508 are formed throughout various layers of the second portion 506 of the IC device 502 in the z direction. Any of the low-density metal zones 508 may be formed based on the footprints of the slits of the blank areas 418 and 420 of the combined fiducial pattern 416.

For example, low-density metal zone 508A is formed based on the footprint of the slit that corresponds to the left side of the blank area 418, low-density metal zone 508B is formed on the footprint of the slit that corresponds to the left side of the blank area 420, low-density metal zone 508C is formed based on the footprint of the slit that corresponds to the right side of the blank area 420, and low-density metal zone 508D is formed based on the footprint of the slit that corresponds to the right side of the blank area 418. Similar low-density metal zones (now shown due to the location of the cross section depicted) may be similarly formed for the top and bottom portions of the blank areas 418 and 420.

Accordingly, the collective low-density metal zones formed in the footprint of the slits of blank area 418 may be a square shaped ring that extends through various layers in the z-direction. Similarly, the collective low-density metal zones formed in the footprint of the slits of blank area 420 may be a smaller square shaped ring that extends through the same layers in the z-direction. In the low-density metal zones, at least some of the layers (e.g., the layers closer to the fiducial which may include thicker metal interconnects) may be completely metal free in the area covered by the zones.

The second IC device 504 may also include a first portion 509 and a second portion 510. In the embodiment depicted, the fiducial pattern 412 may be implemented in a bonding layer of IC device 504 which may be on the top of the device. As depicted, two portions of the metal area 414 are shown (corresponding to portions of the left side and right side of the square shaped ring) on a top layer of the second IC device 504.

The low-density metal zones 508 may allow IR light to pass through the first IC device 502 to the second integrated device 504 when the two devices are bonded together. The passage of this light may allow detection of portions of metal area 414 when the first IC device 502 and the second IC device 504 are misaligned (e.g., misalignment will result in less blank area being detected as the metal area 414 may move within the footprint of the low-density metal zones 508 and block or reflect light that would otherwise be detected). Indeed, the detected dimensions of blank areas (corresponding to light that was not blocked or reflected) may indicate the degree of misalignment in either or both of the x or y direction.

In the embodiment depicted, the low-density metal zones 508A and 508D are wider than the corresponding blank slit 418 in order to allow sufficient allowance to detect the edge of the metal 414 during alignment metrology. Accordingly, in FIG. 5, the inner edges of metal 414 is shown as aligning in the middle of the low-density metal zones 508A and 408D.

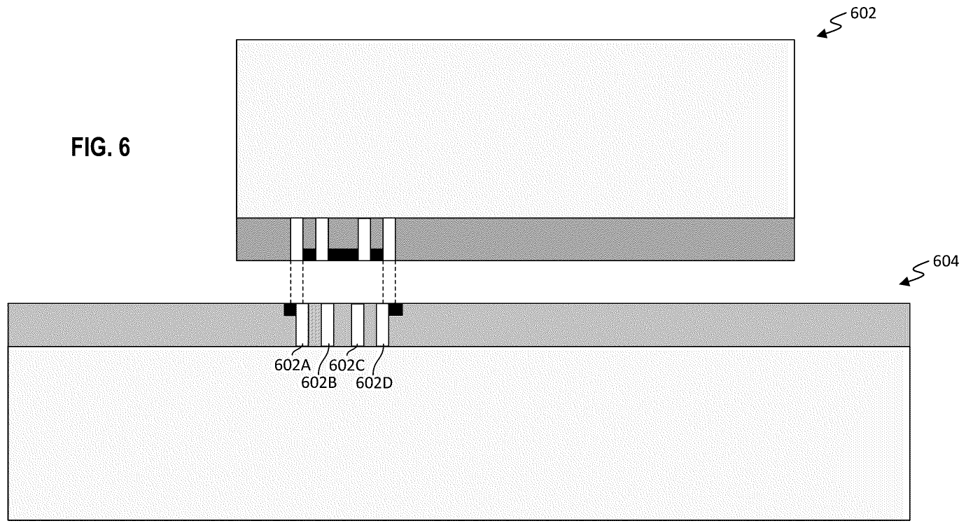

FIG. 6 illustrates an embodiment similar to that shown in FIG. 5, but in FIG. 6, the second IC device 604 also includes low-density metal zones based on the footprint of the blank areas of the combined pattern 416 in the second portion of the second IC device 604. Such an embodiment may be compatible with alignment measurement using a transmissive mode, where the IR light is detected at the bottom of the second device, whereas the embodiment of FIG. 5 is compatible with alignment measurement using a reflective mode.

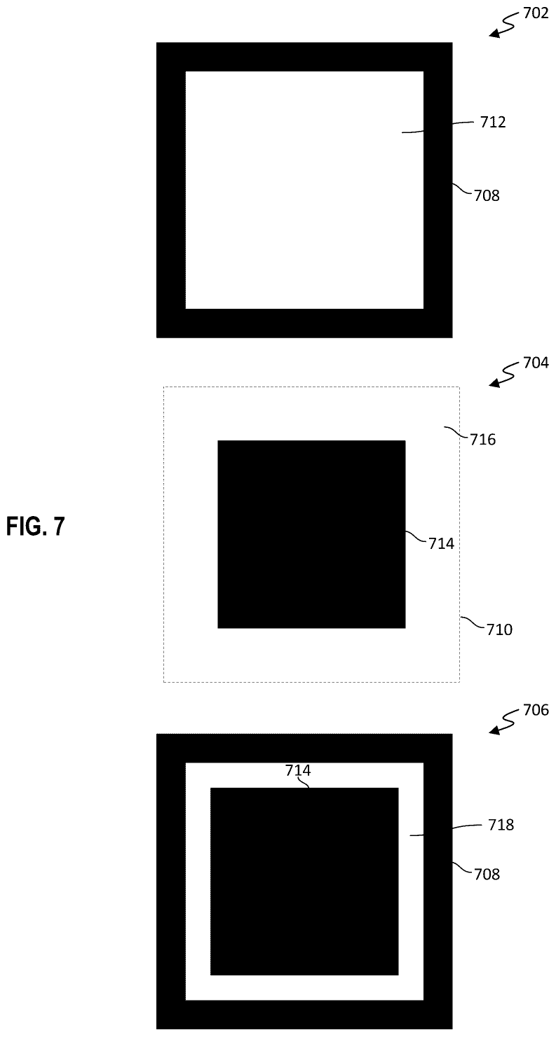

FIG. 7 illustrates additional fiducial patterns 702, 704, and 706 that may serve as the basis for the footprint of low-density metal zones in either or both of a first and second IC device. The patterns are shown as top-down views. Pattern 702 may be implemented on a first IC device (e.g., a top die) and pattern 704 may be implemented on a second IC device (e.g., a base die), or vice versa. Pattern 702 includes a metal area 708 comprising a square shaped ring that has an outer perimeter that defines the fiducial footprint 710 for the pair of fiducials. A blank area 712 comprising a solid square is inside of metal area 708.

Pattern 704 includes a metal area 714 comprising a solid square at the center and a blank area 716 between the metal area 714 and the perimeter defined by the fiducial footprint 710.

Combined pattern 706 represents pattern 702 overlaid on pattern 704 (and thus may be representative of the pattern that may be detected responsive to application of IR light during alignment metrology when the first IC device and the second IC device are perfectly aligned). Combined pattern 706 includes a blank area 718 formed between the metal area 714 and the metal area 708. Similar to the blank areas 418 and 420, the slits of blank area 718 may form footprints for low-density metal zones of a first and/or second IC device that are to be hybrid bonded together.

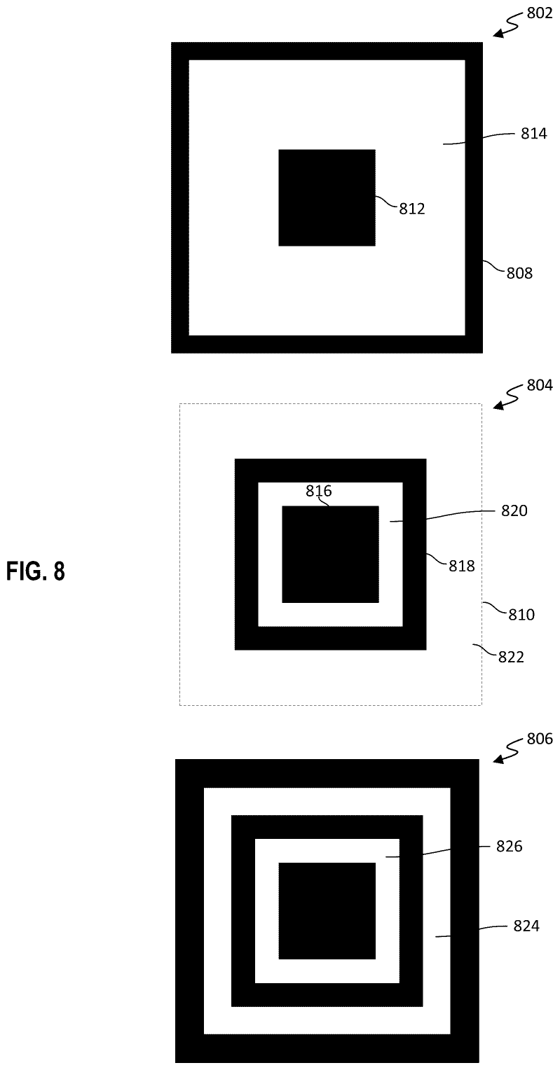

FIG. 8 illustrates additional fiducial patterns 802, 804, and 806 that may serve as the basis for the footprint of low-density metal zones in either or both of a first and second IC device. The patterns are shown as top-down views. Pattern 802 may be implemented on a first IC device (e.g., a top die) and pattern 804 may be implemented on a second IC device (e.g., a base die), or vice versa. Pattern 802 includes a metal area 808 comprising a square shaped ring that has an outer perimeter that defines the fiducial footprint 810 for the pair of fiducials. Pattern 802 also includes a metal area 812 comprising a solid square inside of the metal area 808 (in various embodiments, the metal areas of a fiducial or combined fiducial pattern may be concentric. though in other embodiments they may have different center points). Pattern 802 also includes a blank area 814 that is between the metal area 812 and the metal area 808.

Pattern 804 includes a metal area 816 comprising a solid square at the center and a metal area 818 comprising a square shaped ring around the metal area 816. Pattern 804 also includes a blank area 820 between the metal area 818 and the metal area 816 as well as a blank area 822 between the outer perimeter of the metal area 818 and the fiducial footprint 810.

Combined pattern 806 represents pattern 802 overlaid on pattern 804 (and thus may be representative of the pattern that may be detected responsive to application of IR light during alignment metrology when the first IC device and the second IC device are perfectly aligned). Combined pattern 806 is similar to combined pattern 416 described above. The slits of the blank areas 824 and 826 may each form a footprint for a respective low-density metal zone of a first and/or second IC device that are to be hybrid bonded together (similar to the blank areas 418 and 420 described above).

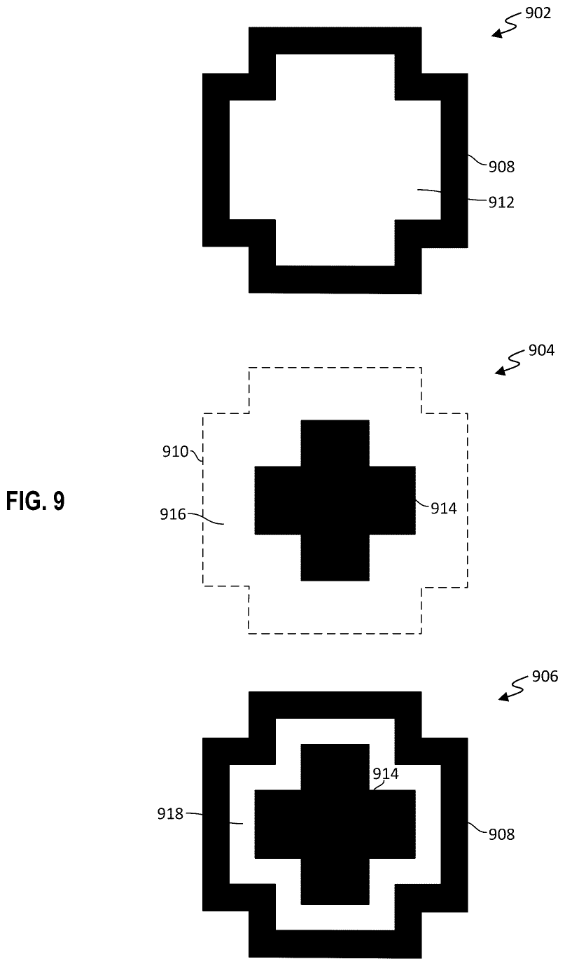

FIG. 9 illustrates additional fiducial patterns 902, 904, and 906 that may serve as the basis for the footprint of low-density metal zones in either or both of a first and second IC device. The patterns are shown as top-down views. Pattern 902 may be implemented on a first IC device (e.g., a top die) and pattern 904 may be implemented on a second IC device (e.g., a base die), or vice versa. Pattern 902 includes a metal area 908 comprising a plus shaped ring that has an outer perimeter that defines the fiducial footprint 910 for the pair of fiducials. Pattern 902 also includes a blank area 912 comprising a solid plus shape that is inside the metal area 908.

Pattern 904 includes a metal area 914 comprising a solid plus shape at the center and a blank area 916 between the outer perimeter of the metal area 914 and fiducial footprint 910.

Pattern 906 represents pattern 902 overlaid on pattern 904 (and thus may be representative of the pattern that may be detected responsive to application of IR light during alignment metrology when the first IC device and the second IC device are perfectly aligned). Pattern 906 includes a blank area 918 with various slits (e.g., a slit for each of the twelve sides of the blank area 918) that form footprints for low-density metal zones of a first and/or second IC device that are to be hybrid bonded together.

As illustrated in FIG. 9, the footprints for the low-density metal zones that are formed in an IC device are not limited to the slits of square shaped rings. Rather the blank area that forms the footprints may take on any suitable shapes that may comprise slits, such as squares (e.g., as illustrated in FIGS. 4, and 7-8), lines, rectangles, triangles, pentagons, hexagons, octagons, circles, X, + (e.g., as illustrated in FIG. 9), or other shapes, rings conforming to such shapes (e.g., shapes bounded by an inner perimeter and outer perimeter having the same shape), or groups of similarly or differently sized shapes (e.g., smaller squares or rectangles). In various embodiments, the metal areas within each of the fiducials are concentric (and thus the combined pattern is expected to be concentric when perfectly aligned, while deviations from such concentricity as detected by alignment metrology may indicate the degree of misalignment in the x and y direction).

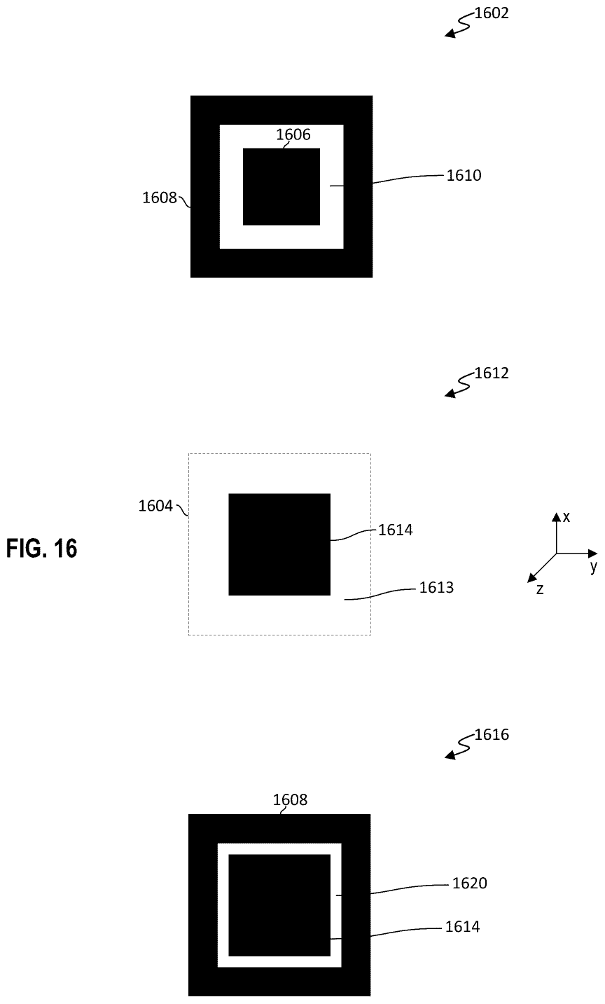

FIG. 16 illustrates additional fiducial patterns 1602, 1612, and 1616 that may serve as the basis for the footprint of low-density metal zones in either or both of a first and second IC device. The patterns are shown as top-down views. Pattern 1602 may be implemented on a first IC device (e.g., a top die) and pattern 1612 may be implemented on a second IC device (e.g., a base die), or vice versa. Pattern 1602 includes a metal area 1608 comprising a square shaped ring. Pattern 1602 also includes metal area 1606 comprising a solid square inside of metal area 1608. A blank area 1610 comprising a square shaped ring is in between metal area 1608 and metal area 1606.

Pattern 1612 includes a metal area 1614 comprising a solid square at the center and a blank area 1613 between the metal area 1614 and the perimeter defined by the fiducial footprint 1604. In this embodiment, the square of metal area 1614 is larger than the square of metal area 1606.

Combined pattern 1616 represents pattern 1602 overlaid on pattern 1612 (and thus may be representative of the pattern that may be detected responsive to application of IR light during alignment metrology when the first IC device and the second IC device are perfectly aligned). Combined pattern 1616 includes a blank area 1620 formed between the metal area 1614 and the metal area 1608. The slits of blank area 1620 may form footprints for low-density metal zones of a first and/or second IC device that are to be hybrid bonded together.

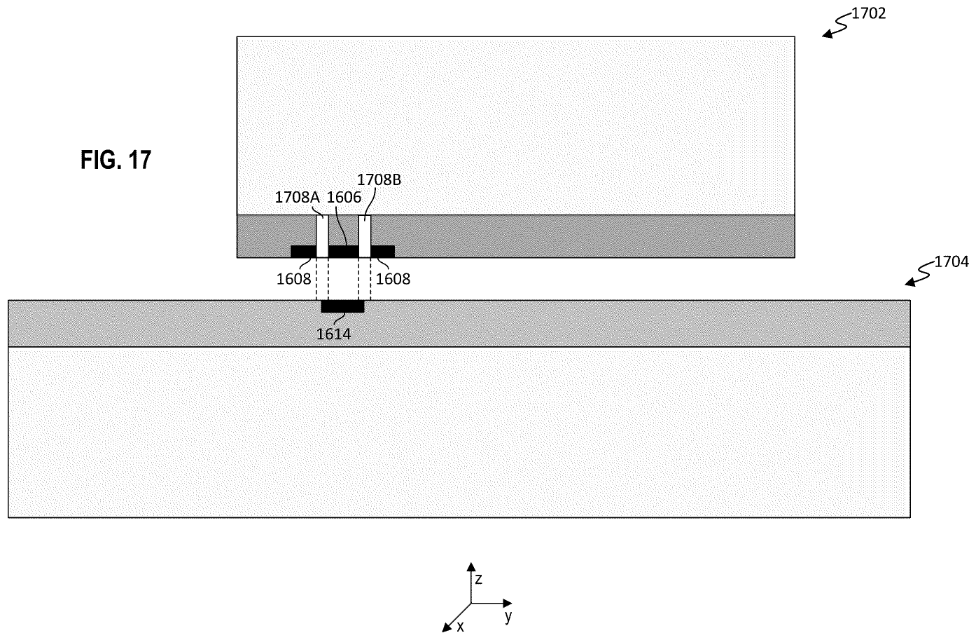

FIG. 17 illustrates a cross section of a first IC device 1702 and a second IC device 1704 (e.g., similar to devices 502 and 504). In order to ensure that sufficient IR light passes through in the appropriate zones during fiducial detection, low-density metal zones 1708A and 1708B corresponding to the slits of the blank areas of combined pattern 1616 may be defined in the second portion of the first IC device 1702.

A cross section (e.g., taken through the center of the fiducial) is shown in FIG. 17. As depicted, the metal area 1606 and left and right portions of metal area 1608 are shown. Low-density metal zones 1708A and 1708B are formed throughout various layers of the second portion of the IC device 1702 in the z direction. Any of the low-density metal zones 1708 may be formed based on the footprints of the slits of the blank area 1620 of the combined fiducial pattern 416. For example, the low-density metal zones 1708 may collectively have a cross section in the x-y plane that is the same as the area of the blank area 1620. As another example, the low-density metal zones 1708 may collectively have a cross section in the x-y plane that includes the blank area 1620 but is larger than the blank area 1620 (e.g., to include additional allowance to detect an edge of the metal area 1614).

In some embodiments, portions of the blank areas shown in the fiducial patterns for the first or second IC devices above could have areas that may or may not include metal. For example, for the portions of the blank areas of the first or second IC devices that do not overlap with the blank areas of the combined pattern (that defines the footprints for the low-density metal zones), these portions may be either metal or metal free as they would not negatively impact the resulting image during alignment detection (unless these portions are needed to be metal free or other low-density metal zones in order to enable detection of an edge of metal in the fiducial of the top die).

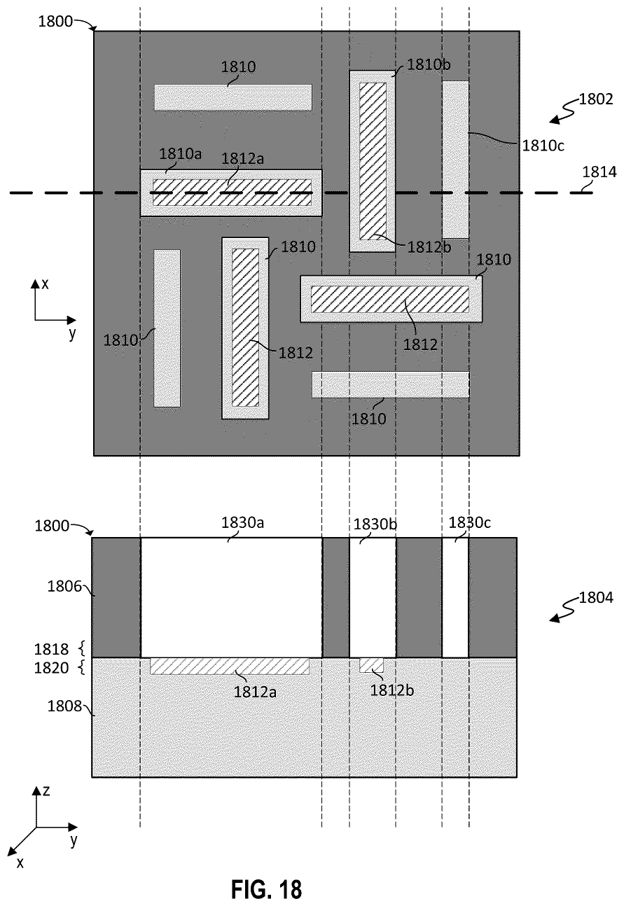

FIG. 18 represents a system 1800 comprising a portion of a first IC device 1806 and a portion of a second IC device 1808 hybrid bonded together. View 1802 depicts a top down view corresponding to a fiducial area of the system when the first and second IC devices are perfectly aligned (e.g., this view may be representative of the view that might be detected by alignment metrology) and view 1804 depicts a side view of a cross section taken along line 1814.

The fiducial area 1818 of the first IC device 1806 comprises a plurality of slits 1810 that each define a footprint for a low-density metal zone 1830 through the first IC device 1806. One or more of these slits (e.g., 1810c) do not have underlying metal areas in the fiducial area 1820 of the second IC device while one or more other slits (e.g., 1810a, 1810b) have underlying metal areas (e.g., 1812a, 1812b) in the fiducial area 1820. In the depicted embodiment, the slits defining low-density metal zones that have underlying metal areas have a footprint that is larger than the underlying metal areas (e.g., a respective underlying metal area 1812 may nest within a corresponding footprint of the corresponding low-density metal zone 1830). In various embodiments, the fiducial area of the first IC device may include one or more slits 1810 that are orthogonal to one or more other slits.

During alignment metrology, the edges of any number of the low-density metal zones corresponding to slits 1810 may be detected as a fiducial mark. For example, the low-density metal zone 1830a corresponding to a slit 1810c may appear differently from the area surrounding the low-density metal zone (as this area may include metal blocking or reflecting the IR light).

For the low-density metal zones that have underlying metal (e.g., 1830a and 1812a), the edges of the underlying metal may be detected as a fiducial mark during alignment metrology and may be compared against one or more other detected fiducial marks to determine alignment metrics.

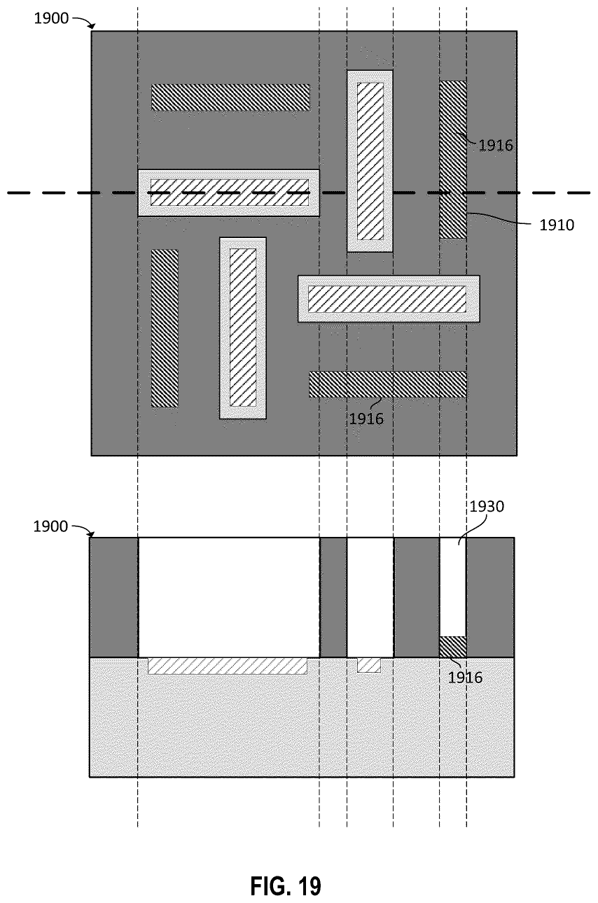

FIG. 19 represents a system 1900 similar to system 1800, but in which some of the metal free zones (e.g., 1930) corresponding to slits (e.g., 1910) include metal 1916 in a fiducial area of the first IC device (e.g., on a top layer or near the top layer). During alignment metrology, this metal may be detected as a fiducial mark.

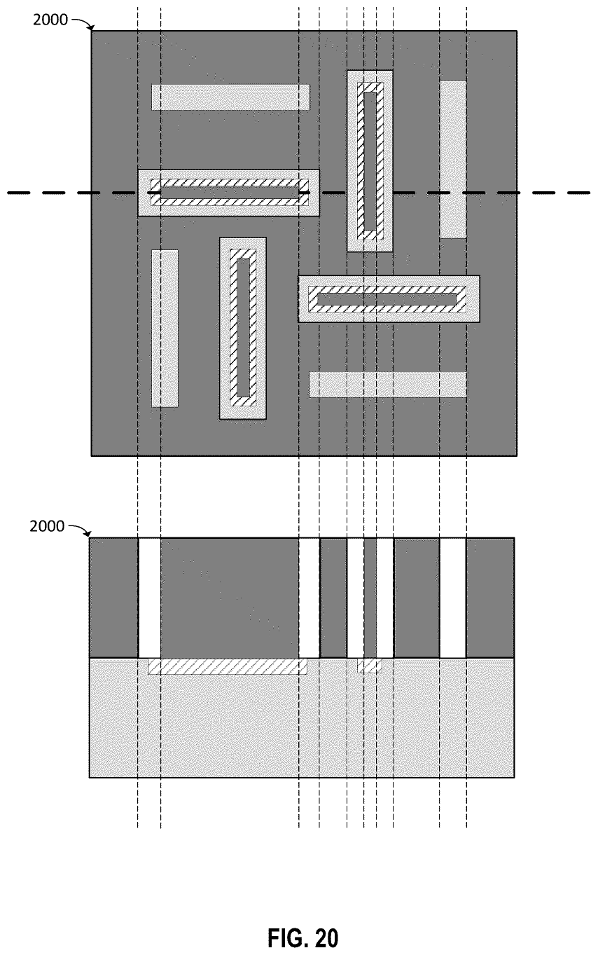

FIG. 20 represents a system 2000 similar to system 1800, but in which the low-density metal zones that have underlying metal in the fiducial area of the second IC device are even smaller (as the corresponding slits comprise rectangle shaped rings). In this system, the other slits are solid rectangles and do not have associated metallization in the fiducial area of the first IC device (similar to system 1800).

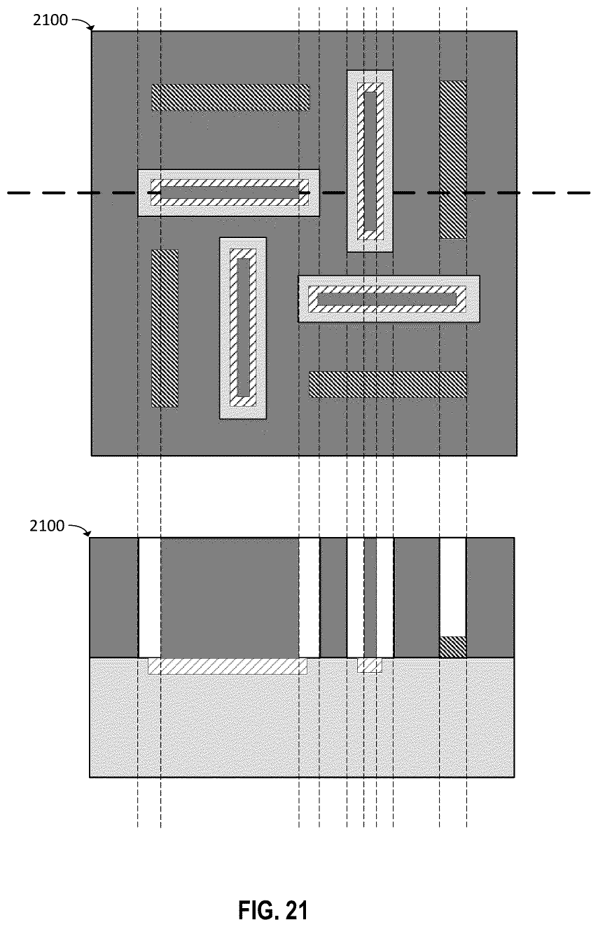

FIG. 21 represents a system 2100 similar to system 2000, but in which the solid rectangular slits do have associated metallization in the fiducial area of the first IC device (similar to system 1900).

In various embodiments, the shorter dimensions of the slits may be between 1 and 10 microns, while the longer dimensions of the slits may be between 5 microns to 30 microns, although in other embodiments other dimensions may be used.

In other embodiments, the groups of slits depicted in FIGS. 18-21 may have any other suitable shapes (such as those described herein).

In various embodiments, the total fiducial footprint may be any suitable size, such as within the range of 30×30 microns to 100×100 microns (while the fiducial footprint area is not limited to the shape of a square). In various embodiments, the width of the slits in the blank area that form the footprints for the low-density metal zones (and thus the widths of the low-density metal zones themselves) may be, e.g., between 1-10 microns. In some embodiments, the width of one or more rings in the combined fiducial may be the same as the width of slits blank areas in the combined fiducial (in other embodiments, these widths may differ). In various embodiments, the width of the rings may be between 1 and 10 microns.

In one embodiment, the fiducial footprint is approximately 50×50 microns and the width of the slits and rings within the fiducial are approximately 5 microns.

The slits (and their corresponding low-density metal zones) may be relatively long and narrow. For example, a length of a particular slit may be more than 2×, 3×, or 5× the respective width.

As described above, the metal of the fiducials may comprise any suitable metal such as copper, aluminum, tungsten, or metal alloy. In some embodiments, the metal of the fiducials may include a metal that is used for metal interconnects on the same or different layer as the fiducial. The underlying low-density metal zones may include, e.g., an ILD material.

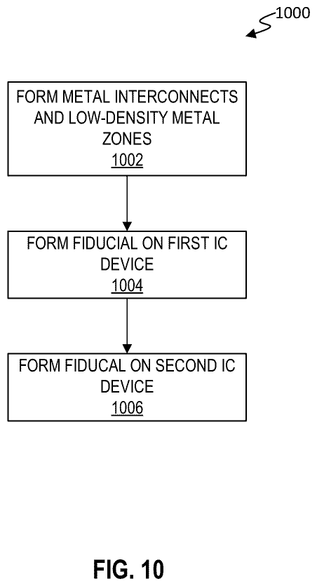

FIG. 10 illustrates a process for forming fiducials with associated low-density metal zones. At 1002, metal interconnects and low-density metal zones 1002 are formed on metal interconnect layers of a first and/or second IC device. In various embodiments, this may include omitting metal patterning within any areas of the layers that are within the low-density metal zones. At 1004, a fiducial is formed on a first IC device. At 1006, a fiducial is formed on a second IC device. The fiducial of the second IC device is associated with the fiducial of the first IC device, but may not match the design of the fiducial of the first IC device.

Although FIG. 10 shows example blocks of process 1000, in some implementations, process 1000 may include additional blocks, fewer blocks, different blocks, or differently arranged blocks than those depicted in FIG. 10. Additionally, or alternatively, two or more of the blocks of process 1000 may be performed in parallel.

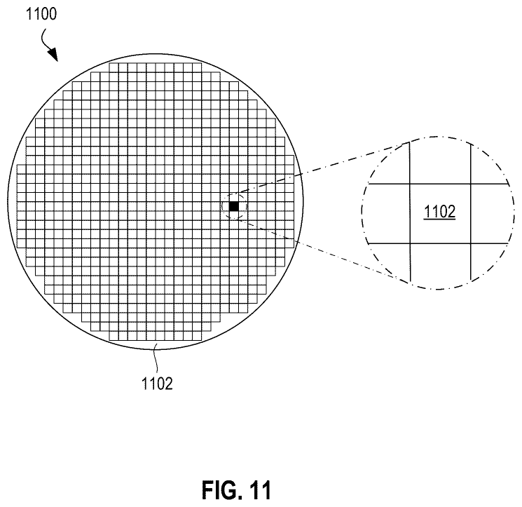

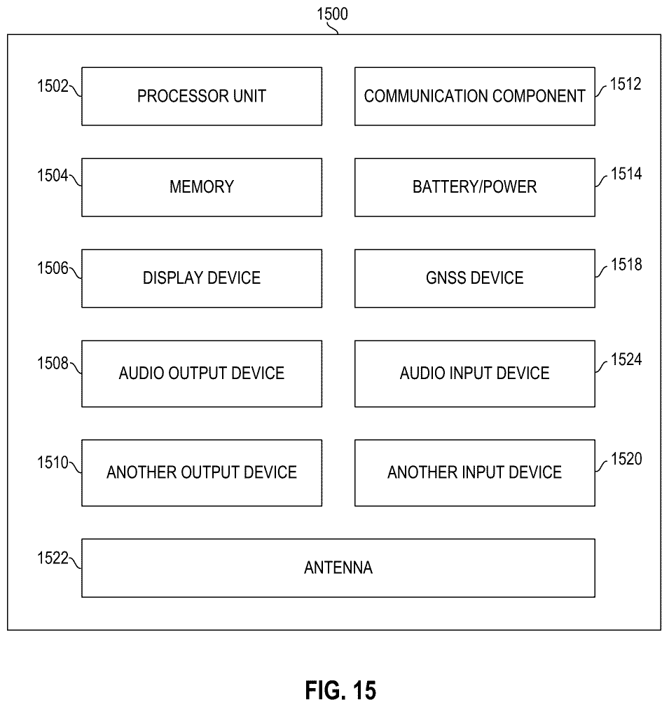

FIG. 11 is a top view of a wafer 1100 and dies 1102 wherein individual dies may include fiducials with associated low-density metal zones as described herein. The wafer 1100 may be composed of semiconductor material and may include one or more dies 1102 having integrated circuit structures formed on a surface of the wafer 1100. The individual dies 1102 may be a repeating unit of an integrated circuit product that includes any suitable integrated circuit. After the fabrication of the semiconductor product is complete, the wafer 1100 may undergo a singulation process in which the dies 1102 are separated from one another to provide discrete “chips” of the integrated circuit product. The die 1102 may include one or more transistors supporting circuitry to route electrical signals to the transistors, passive components (e.g., signal traces, resistors, capacitors, or inductors), and/or any other integrated circuit components. In some embodiments, the wafer 1100 or the die 1102 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 1102. For example, a memory array formed by multiple memory devices may be formed on a same die 1102 as a processor unit (e.g., the processor unit 1502 of FIG. 15) or other logic that is configured to store information in the memory devices or execute instructions stored in the memory array. Various ones of the microelectronic assemblies disclosed herein may be manufactured using a die-to-wafer assembly technique in which some dies are attached to a wafer 1100 that include other dies, and the wafer 1100 is subsequently singulated.

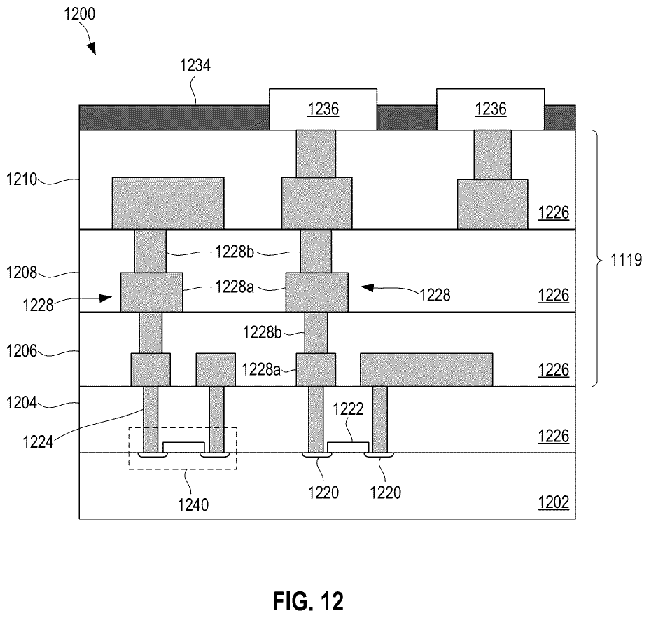

FIG. 12 is a cross-sectional side view of an integrated circuit device 1200 that may include fiducials with associated low-density metal zones as described herein. One or more of the integrated circuit devices 1200 may be included in one or more dies 1102 (FIG. 11). The integrated circuit device 1200 may be formed on a die substrate 1202 (e.g., the wafer 1100 of FIG. 11) and may be included in a die (e.g., the die 1102 of FIG. 11). The die substrate 1202 may be a semiconductor substrate composed of semiconductor material systems including, for example, n-type or p-type materials systems (or a combination of both). The die substrate 1202 may include, for example, a crystalline substrate formed using a bulk silicon or a silicon-on-insulator (SOI) substructure. In some embodiments, the die substrate 1202 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 1202. Although a few examples of materials from which the die substrate 1202 may be formed are described here, any material that may serve as a foundation for an integrated circuit device 1200 may be used. The die substrate 1202 may be part of a singulated die (e.g., the dies 1102 of FIG. 11) or a wafer (e.g., the wafer 1100 of FIG. 11).

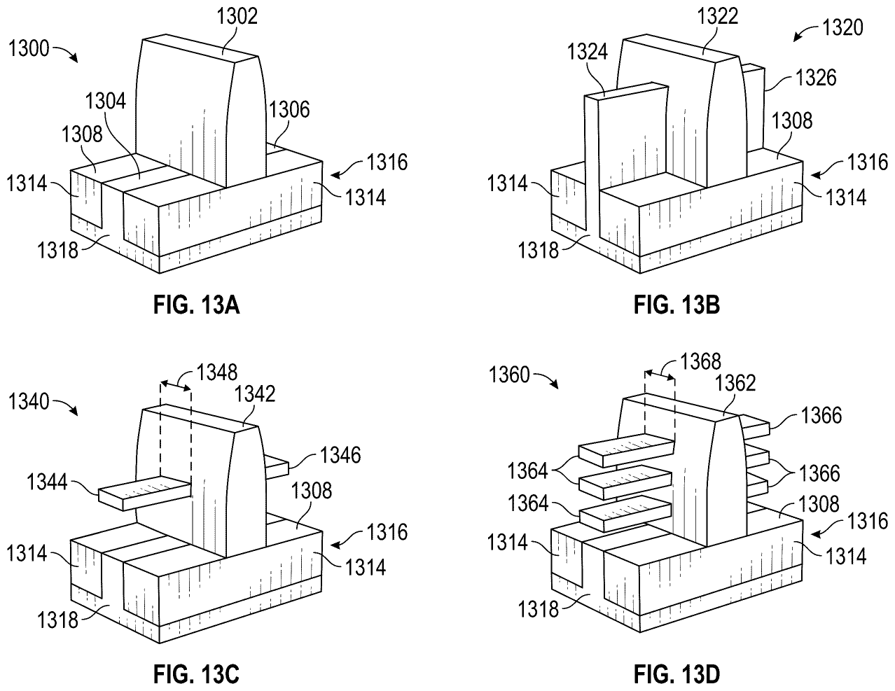

The integrated circuit device 1200 may include one or more device layers 1204 disposed on the die substrate 1202. The device layer 1204 may include features of one or more transistors 1240 (e.g., metal oxide semiconductor field-effect transistors (MOSFETs)) formed on the die substrate 1202. The transistors 1240 may include, for example, one or more source and/or drain (S/D) regions 1220, a gate 1222 to control current flow between the S/D regions 1220, and one or more S/D contacts 1224 to route electrical signals to/from the S/D regions 1220. The transistors 1240 may include additional features not depicted for the sake of clarity, such as device isolation regions, gate contacts, and the like. The transistors 1240 are not limited to the type and configuration depicted in FIG. 12 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors. Examples of non-planar transistors will be described in connection with FIGS. 13A-13D.

A transistor 1240 may include a gate 1222 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1240 is to be a p-type metal oxide semiconductor (PMOS) or an n-type metal oxide semiconductor (NMOS) transistor. In some implementations, the gate electrode may consist of or comprise a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1240 along the source-channel-drain direction, the gate electrode may consist of or comprise a U-shaped structure that includes a bottom portion substantially parallel to the surface of the die substrate 1202 and two sidewall portions that are substantially perpendicular to the top surface of the die substrate 1202. In other embodiments, at least one of the metal layers that form the gate electrode may simply be a planar layer that is substantially parallel to the top surface of the die substrate 1202 and does not include sidewall portions substantially perpendicular to the top surface of the die substrate 1202. In other embodiments, the gate electrode may consist of or comprise a combination of U-shaped structures and planar, non-U-shaped structures. For example, the gate electrode may consist of or comprise one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1220 may be formed within the die substrate 1202 adjacent to the gate 1222 of individual transistors 1240. The S/D regions 1220 may be formed using an implantation/diffusion process or an etching/deposition process, for example. In the former process, dopants such as boron, aluminum, antimony, phosphorous, or arsenic may be ion-implanted into the die substrate 1202 to form the S/D regions 1220. An annealing process that activates the dopants and causes them to diffuse farther into the die substrate 1202 may follow the ion-implantation process. In the latter process, the die substrate 1202 may first be etched to form recesses at the locations of the S/D regions 1220. An epitaxial deposition process may then be carried out to fill the recesses with material that is used to fabricate the S/D regions 1220. In some implementations, the S/D regions 1220 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1220 may be formed using one or more alternate semiconductor materials such as germanium or a group III-V material or alloy. In further embodiments, one or more layers of metal and/or metal alloys may be used to form the S/D regions 1220.

Electrical signals, such as power and/or input/output (I/O) signals, may be routed to and/or from the devices (e.g., transistors 1240) of the device layer 1204 through one or more interconnect layers disposed on the device layer 1204 (illustrated in FIG. 12 as interconnect layers 1206-1210). For example, electrically conductive features of the device layer 1204 (e.g., the gate 1222 and the S/D contacts 1224) may be electrically coupled with the interconnect structures 1228 of the interconnect layers 1206-1210. The one or more interconnect layers 1206-1210 may form a metallization stack (also referred to as an “ILD stack”) 1219 of the integrated circuit device 1200.

The interconnect structures 1228 (e.g., lines) may be arranged within the interconnect layers 1206-1210 to route electrical signals according to a wide variety of designs; in particular, the arrangement is not limited to the particular configuration of interconnect structures 1228 depicted in FIG. 12. Although a particular number of interconnect layers 1206-1210 is depicted in FIG. 12, embodiments of the present disclosure include integrated circuit devices having more or fewer interconnect layers than depicted.

In some embodiments, the interconnect structures 1228 may include lines 1228a and/or vias 1228b filled with an electrically conductive material such as a metal. The lines 1228a may be arranged to route electrical signals in a direction of a plane that is substantially parallel with a surface of the die substrate 1202 upon which the device layer 1204 is formed. For example, the lines 1228a may route electrical signals in a direction in and out of the page and/or in a direction across the page. The vias 1228b may be arranged to route electrical signals in a direction of a plane that is substantially perpendicular to the surface of the die substrate 1202 upon which the device layer 1204 is formed. In some embodiments, the vias 1228b may electrically couple lines 1228a of different interconnect layers 1206-1210 together.

The interconnect layers 1206-1210 may include a dielectric material 1226 disposed between the interconnect structures 1228, as shown in FIG. 12. In some embodiments, dielectric material 1226 disposed between the interconnect structures 1228 in different ones of the interconnect layers 1206-1210 may have different compositions; in other embodiments, the composition of the dielectric material 1226 between different interconnect layers 1206-1210 may be the same. The device layer 1204 may include a dielectric material 1226 disposed between the transistors 1240 and a bottom layer of the metallization stack as well. The dielectric material 1226 included in the device layer 1204 may have a different composition than the dielectric material 1226 included in the interconnect layers 1206-1210; in other embodiments, the composition of the dielectric material 1226 in the device layer 1204 may be the same as a dielectric material 1226 included in any one of the interconnect layers 1206-1210.

A first interconnect layer 1206 (referred to as Metal 1 or “M1”) may be formed directly on the device layer 1204. In some embodiments, the first interconnect layer 1206 may include lines 1228a and/or vias 1228b, as shown. The lines 1228a of the first interconnect layer 1206 may be coupled with contacts (e.g., the S/D contacts 1224) of the device layer 1204. The vias 1228b of the first interconnect layer 1206 may be coupled with the lines 1228a of a second interconnect layer 1208.

The second interconnect layer 1208 (referred to as Metal 2 or “M2”) may be formed directly on the first interconnect layer 1206. In some embodiments, the second interconnect layer 1208 may include via 1228b to couple the interconnect structures 1228 of the second interconnect layer 1208 with the lines 1228a of a third interconnect layer 1210. Although the lines 1228a and the vias 1228b are structurally delineated with a line within individual interconnect layers for the sake of clarity, the lines 1228a and the vias 1228b may be structurally and/or materially contiguous (e.g., simultaneously filled during a dual-damascene process) in some embodiments.

The third interconnect layer 1210 (referred to as Metal 3 or “M3”) (and additional interconnect layers, as desired) may be formed in succession on the second interconnect layer 1208 according to similar techniques and configurations described in connection with the second interconnect layer 1208 or the first interconnect layer 1206. In some embodiments, the interconnect layers that are “higher up” in the metallization stack 1219 in the integrated circuit device 1200 (e.g., farther away from the device layer 1204) may be thicker that the interconnect layers that are lower in the metallization stack 1219, with lines 1228a and vias 1228b in the higher interconnect layers being thicker than those in the lower interconnect layers.

The integrated circuit device 1200 may include a solder resist material 1234 (e.g., polyimide or similar material) and one or more conductive contacts 1236 formed on the interconnect layers 1206-1210. In FIG. 12, the conductive contacts 1236 are illustrated as taking the form of bond pads. The conductive contacts 1236 may be electrically coupled with the interconnect structures 1228 and configured to route the electrical signals of the transistor(s) 1240 to external devices. For example, solder bonds may be formed on the one or more conductive contacts 1236 to mechanically and/or electrically couple an integrated circuit die including the integrated circuit device 1200 with another component (e.g., a printed circuit board). The integrated circuit device 1200 may include additional or alternate structures to route the electrical signals from the interconnect layers 1206-1210; for example, the conductive contacts 1236 may include other analogous features (e.g., posts) that route the electrical signals to external components.

In some embodiments in which the integrated circuit device 1200 is a double-sided die, the integrated circuit device 1200 may include another metallization stack (not shown) on the opposite side of the device layer(s) 1204. This metallization stack may include multiple interconnect layers as discussed above with reference to the interconnect layers 1206-1210, to provide conductive pathways (e.g., including conductive lines and vias) between the device layer(s) 1204 and additional conductive contacts (not shown) on the opposite side of the integrated circuit device 1200 from the conductive contacts 1236.

In other embodiments in which the integrated circuit device 1200 is a double-sided die, the integrated circuit device 1200 may include one or more through silicon vias (TSVs) through the die substrate 1202; these TSVs may make contact with the device layer(s) 1204, and may provide conductive pathways between the device layer(s) 1204 and additional conductive contacts (not shown) on the opposite side of the integrated circuit device 1200 from the conductive contacts 1236. In some embodiments, TSVs extending through the substrate can be used for routing power and ground signals from conductive contacts on the opposite side of the integrated circuit device 1200 from the conductive contacts 1236 to the transistors 1240 and any other components integrated into the integrated circuit device (e.g., die) 1200, and the metallization stack 1219 can be used to route I/O signals from the conductive contacts 1236 to transistors 1240 and any other components integrated into the integrated circuit device (e.g., die) 1200.

Multiple integrated circuit devices 1200 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIGS. 13A-13D are simplified perspective views of example planar, FinFET, gate-all-around, and stacked gate-all-around transistors. The transistors illustrated in FIGS. 13A-13D are formed on a substrate 1316 having a surface 1308. Isolation regions 1314 separate the source and drain regions of the transistors from other transistors and from a bulk region 1318 of the substrate 1316.

FIG. 13A is a perspective view of an example planar transistor 1300 comprising a gate 1302 that controls current flow between a source region 1304 and a drain region 1306. The transistor 1300 is planar in that the source region 1304 and the drain region 1306 are planar with respect to the substrate surface 1308.

FIG. 13B is a perspective view of an example FinFET transistor 1320 comprising a gate 1322 that controls current flow between a source region 1324 and a drain region 1326. The transistor 1320 is non-planar in that the source region 1324 and the drain region 1326 comprise “fins” that extend upwards from the substrate surface 1308. As the gate 1322 encompasses three sides of the semiconductor fin that extends from the source region 1324 to the drain region 1326, the transistor 1320 can be considered a tri-gate transistor. FIG. 13B illustrates one S/D fin extending through the gate 1322, but multiple S/D fins can extend through the gate of a FinFET transistor.

FIG. 13C is a perspective view of a gate-all-around (GAA) transistor 1340 comprising a gate 1342 that controls current flow between a source region 1344 and a drain region 1346. The transistor 1340 is non-planar in that the source region 1344 and the drain region 1346 are elevated from the substrate surface 1308.

FIG. 13D is a perspective view of a GAA transistor 1360 comprising a gate 1362 that controls current flow between multiple elevated source regions 1364 and multiple elevated drain regions 1366. The transistor 1360 is a stacked GAA transistor as the gate controls the flow of current between multiple elevated S/D regions stacked on top of each other. The transistors 1340 and 1360 are considered gate-all-around transistors as the gates encompass all sides of the semiconductor portions that extends from the source regions to the drain regions. The transistors 1340 and 1360 can alternatively be referred to as nanowire, nanosheet, or nanoribbon transistors depending on the width (e.g., widths 1348 and 1368 of transistors 1340 and 1360, respectively) of the semiconductor portions extending through the gate.

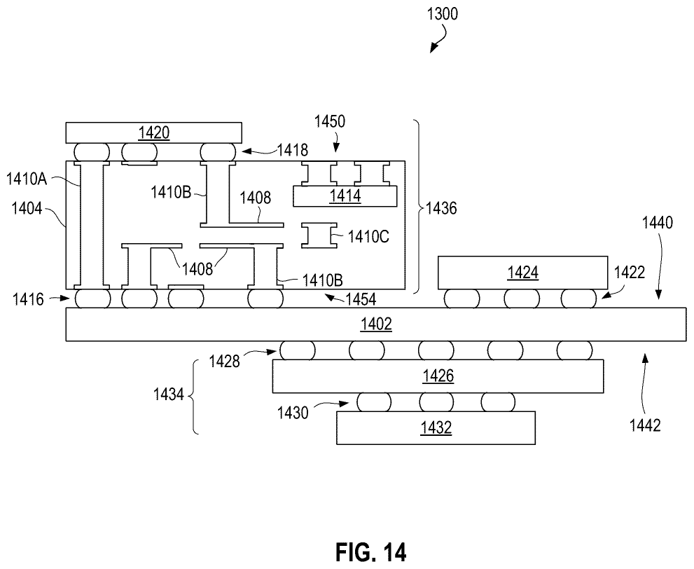

FIG. 14 is a cross-sectional side view of an integrated circuit device assembly 1400 that may include fiducials with associated low-density metal zones as described herein. The integrated circuit device assembly 1400 includes a number of components disposed on a circuit board 1402 (which may be a motherboard, system board, mainboard, etc.). The integrated circuit device assembly 1400 includes components disposed on a first face 1440 of the circuit board 1402 and an opposing second face 1442 of the circuit board 1402; generally, components may be disposed on one or both faces 1440 and 1442.

In some embodiments, the circuit board 1402 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the circuit board 1402. In other embodiments, the circuit board 1402 may be a non-PCB substrate. The integrated circuit device assembly 1400 illustrated in FIG. 14 includes a package-on-interposer structure 1436 coupled to the first face 1440 of the circuit board 1402 by coupling components 1416. The coupling components 1416 may electrically and mechanically couple the package-on-interposer structure 1436 to the circuit board 1402, and may include solder balls (as shown in FIG. 14), pins (e.g., as part of a pin grid array (PGA), contacts (e.g., as part of a land grid array (LGA)), male and female portions of a socket, an adhesive, an underfill material, and/or any other suitable electrical and/or mechanical coupling structure.

The package-on-interposer structure 1436 may include an integrated circuit component 1420 coupled to an interposer 1404 by coupling components 1418. The coupling components 1418 may take any suitable form for the application, such as the forms discussed above with reference to the coupling components 1416. Although a single integrated circuit component 1420 is shown in FIG. 14, multiple integrated circuit components may be coupled to the interposer 1404; indeed, additional interposers may be coupled to the interposer 1404. The interposer 1404 may provide an intervening substrate used to bridge the circuit board 1402 and the integrated circuit component 1420.

The integrated circuit component 1420 may be a packaged or unpackaged integrated circuit product that includes one or more integrated circuit dies (e.g., the die 1102 of FIG. 11, the integrated circuit device 1200 of FIG. 12) and/or one or more other suitable components. A packaged integrated circuit component comprises one or more integrated circuit dies mounted on a package substrate with the integrated circuit dies and package substrate encapsulated in a casing material, such as a metal, plastic, glass, or ceramic. In one example of an unpackaged integrated circuit component 1420, a single monolithic integrated circuit die comprises solder bumps attached to contacts on the die. The solder bumps allow the die to be directly attached to the interposer 1404. The integrated circuit component 1420 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the integrated circuit component 1420 can comprise one or more additional active or passive devices such as capacitors, decoupling capacitors, resistors, inductors, fuses, diodes, transformers, sensors, electrostatic discharge (ESD) devices, and memory devices.

In embodiments where the integrated circuit component 1420 comprises multiple integrated circuit dies, the dies can be of the same type (a homogeneous multi-die integrated circuit component) or of two or more different types (a heterogeneous multi-die integrated circuit component). A multi-die integrated circuit component can be referred to as a multi-chip package (MCP) or multi-chip module (MCM).

In addition to comprising one or more processor units, the integrated circuit component 1420 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

Generally, the interposer 1404 may spread connections to a wider pitch or reroute a connection to a different connection. For example, the interposer 1404 may couple the integrated circuit component 1420 to a set of ball grid array (BGA) conductive contacts of the coupling components 1416 for coupling to the circuit board 1402. In the embodiment illustrated in FIG. 14, the integrated circuit component 1420 and the circuit board 1402 are attached to opposing sides of the interposer 1404; in other embodiments, the integrated circuit component 1420 and the circuit board 1402 may be attached to a same side of the interposer 1404. In some embodiments, three or more components may be interconnected by way of the interposer 1404.

In some embodiments, the interposer 1404 may be formed as a PCB, including multiple metal layers separated from one another by layers of dielectric material and interconnected by electrically conductive vias. In some embodiments, the interposer 1404 may be formed of an epoxy resin, a fiberglass-reinforced epoxy resin, an epoxy resin with inorganic fillers, a ceramic material, or a polymer material such as polyimide. In some embodiments, the interposer 1404 may be formed of alternate rigid or flexible materials that may include the same materials described above for use in a semiconductor substrate, such as silicon, germanium, and other group III-V and group IV materials. The interposer 1404 may include metal interconnects 1408 and vias 1410, including but not limited to through hole vias 1410A (that extend from a first face 1450 of the interposer 1404 to a second face 1454 of the interposer 1404), blind vias 1410B (that extend from the first or second faces 1450 or 1454 of the interposer 1404 to an internal metal layer), and buried vias 1410C (that connect internal metal layers).

In some embodiments, the interposer 1404 can comprise a silicon interposer. Through silicon vias (TSV) extending through the silicon interposer can connect connections on a first face of a silicon interposer to an opposing second face of the silicon interposer. In some embodiments, an interposer 1404 comprising a silicon interposer can further comprise one or more routing layers to route connections on a first face of the interposer 1404 to an opposing second face of the interposer 1404.

The interposer 1404 may further include embedded devices 1414, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1404. The package-on-interposer structure 1436 may take the form of any of the package-on-interposer structures known in the art.

The integrated circuit device assembly 1400 may include an integrated circuit component 1424 coupled to the first face 1440 of the circuit board 1402 by coupling components 1422. The coupling components 1422 may take the form of any of the embodiments discussed above with reference to the coupling components 1416, and the integrated circuit component 1424 may take the form of any of the embodiments discussed above with reference to the integrated circuit component 1420.

The integrated circuit device assembly 1400 illustrated in FIG. 14 includes a package-on-package structure 1434 coupled to the second face 1442 of the circuit board 1402 by coupling components 1428. The package-on-package structure 1434 may include an integrated circuit component 1426 and an integrated circuit component 1432 coupled together by coupling components 1430 such that the integrated circuit component 1426 is disposed between the circuit board 1402 and the integrated circuit component 1432. The coupling components 1428 and 1430 may take the form of any of the embodiments of the coupling components 1416 discussed above, and the integrated circuit components 1426 and 1432 may take the form of any of the embodiments of the integrated circuit component 1420 discussed above. The package-on-package structure 1434 may be configured in accordance with any of the package-on-package structures known in the art.

FIG. 15 is a block diagram of an example electrical device 1500 that may include fiducials with associated low-density metal zones as described herein. For example, any suitable ones of the components of the electrical device 1500 may include one or more of the integrated circuit dies 1102, integrated circuit devices 1200, integrated circuit device assemblies 1400, integrated circuit components 1420, or other components disclosed herein. A number of components are illustrated in FIG. 15 as included in the electrical device 1500, but any one or more of these components may be omitted or duplicated, as suitable for the application. In some embodiments, some or all of the components included in the electrical device 1500 may be attached to one or more motherboards mainboards, or system boards. In some embodiments, one or more of these components are fabricated onto a single system-on-a-chip (SoC) die.

Additionally, in various embodiments, the electrical device 1500 may not include one or more of the components illustrated in FIG. 15, but the electrical device 1500 may include interface circuitry for coupling to the one or more components. For example, the electrical device 1500 may not include a display device 1506, but may include display device interface circuitry (e.g., a connector and driver circuitry) to which a display device 1506 may be coupled. In another set of examples, the electrical device 1500 may not include an audio input device 1524 or an audio output device 1508, but may include audio input or output device interface circuitry (e.g., connectors and supporting circuitry) to which an audio input device 1524 or audio output device 1508 may be coupled.

The electrical device 1500 may include one or more processor units 1502 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1502 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1500 may include a memory 1504, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1504 may include memory that is located on the same integrated circuit die as the processor unit 1502. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1500 can comprise one or more processor units 1502 that are heterogeneous or asymmetric to another processor unit 1502 in the electrical device 1500. There can be a variety of differences between the processing units 1502 in a system in terms of a spectrum of metrics of merit including architectural, microarchitectural, thermal, power consumption characteristics, and the like. These differences can effectively manifest themselves as asymmetry and heterogeneity among the processor units 1502 in the electrical device 1500.

In some embodiments, the electrical device 1500 may include a communication component 1512 (e.g., one or more communication components). For example, the communication component 1512 can manage wireless communications for the transfer of data to and from the electrical device 1500. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1512 may implement any of a number of wireless standards or protocols, including but not limited to Institute for Electrical and Electronic Engineers (IEEE) standards including Wi-Fi (IEEE 1202.11 family), IEEE 1202.16 standards (e.g., IEEE 1202.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 1202.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 1202.16 standards. The communication component 1512 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1512 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1512 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1512 may operate in accordance with other wireless protocols in other embodiments. The electrical device 1500 may include an antenna 1522 to facilitate wireless communications and/or to receive other wireless communications (such as amplitude modulation (AM) or frequency modulation (FM) radio transmissions).

In some embodiments, the communication component 1512 may manage wired communications, such as electrical, optical, or any other suitable communication protocols (e.g., IEEE 1202.3 Ethernet standards). As noted above, the communication component 1512 may include multiple communication components. For instance, a first communication component 1512 may be dedicated to shorter-range wireless communications such as Wi-Fi or Bluetooth, and a second communication component 1512 may be dedicated to longer-range wireless communications such as global positioning system (GPS), EDGE, GPRS, CDMA, WiMAX, LTE, EV-DO, or others. In some embodiments, a first communication component 1512 may be dedicated to wireless communications, and a second communication component 1512 may be dedicated to wired communications.

The electrical device 1500 may include battery/power circuitry 1514. The battery/power circuitry 1514 may include one or more energy storage devices (e.g., batteries or capacitors) and/or circuitry for coupling components of the electrical device 1500 to an energy source separate from the electrical device 1500 (e.g., AC line power).

The electrical device 1500 may include a display device 1506 (or corresponding interface circuitry, as discussed above). The display device 1506 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1500 may include an audio output device 1508 (or corresponding interface circuitry, as discussed above). The audio output device 1508 may include any embedded or wired or wirelessly connected external device that generates an audible indicator, such speakers, headsets, or earbuds.

The electrical device 1500 may include an audio input device 1524 (or corresponding interface circuitry, as discussed above). The audio input device 1524 may include any embedded or wired or wirelessly connected device that generates a signal representative of a sound, such as microphones, microphone arrays, or digital instruments (e.g., instruments having a musical instrument digital interface (MIDI) output). The electrical device 1500 may include a Global Navigation Satellite System (GNSS) device 1518 (or corresponding interface circuitry, as discussed above), such as a Global Positioning System (GPS) device. The GNSS device 1518 may be in communication with a satellite-based system and may determine a geolocation of the electrical device 1500 based on information received from one or more GNSS satellites, as known in the art.

The electrical device 1500 may include another output device 1510 (or corresponding interface circuitry, as discussed above). Examples of the other output device 1510 may include an audio codec, a video codec, a printer, a wired or wireless transmitter for providing information to other devices, or an additional storage device.

The electrical device 1500 may include another input device 1520 (or corresponding interface circuitry, as discussed above). Examples of the other input device 1520 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1500 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra-mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1500 may be any other electronic device that processes data. In some embodiments, the electrical device 1500 may comprise multiple discrete physical components. Given the range of devices that the electrical device 1500 can be manifested as in various embodiments, in some embodiments, the electrical device 1500 can be referred to as a computing device or a computing system.

Throughout this specification, plural instances may implement components, operations, or structures described as a single instance. Although individual operations of one or more methods are illustrated and described as separate operations, one or more of the individual operations may be performed concurrently, and nothing requires that the operations be performed in the order illustrated. Structures and functionality presented as separate components in example configurations may be implemented as a combined structure or component. Similarly, structures and functionality presented as a single component may be implemented as separate components. These and other variations, modifications, additions, and improvements fall within the scope of the subject matter herein.

It will also be understood that, although the terms “first,” “second,” and so forth may be used herein to describe various elements, these elements should not be limited by these terms. These terms are only used to distinguish one element from another, and are not intended to imply that the objects so described must be in a given sequence, either temporally, spatially, in ranking or in any other manner. For example, a first contact could be termed a second contact, and, similarly, a second contact could be termed a first contact, without departing from the scope of the present example embodiments. The first contact and the second contact are both contacts, but they are not the same contact.

As used in the description of the example embodiments and the appended examples, the singular forms “a,” “an,” and “the” are intended to include the plural forms as well, unless the context clearly indicates otherwise. It will also be understood that the term “and/or” as used herein refers to and encompasses any and all possible combinations of one or more of the associated listed items. For example, the phrase “A and/or B” means (A), (B), or (A and B), while the phrase “A, B, and/or C” means (A), (B), (C), (A and B), (A and C), (B and C), or (A, B, and C).

As used throughout this description, and in the claims, a list of items joined by the term “at least one of” or “one or more of” can mean any combination of the listed terms.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. Furthermore, the terms “comprising,” “including,” “having,” and the like, as used with respect to embodiments of the present disclosure, are synonymous.

The description may use the phrases “in an embodiment,” “according to some embodiments,” “in accordance with embodiments,” or “in embodiments,” which may each refer to one or more of the same or different embodiments.

As used herein, the term “module” refers to being part of, or including an ASIC, an electronic circuit, a system on a chip, a processor (shared, dedicated, or group), a solid state device, a memory (shared, dedicated, or group) that execute one or more software or firmware programs, a combinational logic circuit, and/or other suitable components that provide the described functionality.

As used herein, “electrically conductive” in some examples may refer to a property of a material having an electrical conductivity greater than or equal to 107 Siemens per meter (S/m) at 20 degrees Celsius. Examples of such materials include Cu, Ag. Al, Au, W, Zn and Ni.

The term “signal” may refer to at least one current signal, voltage signal, magnetic signal, or data/clock signal.

Throughout the specification, and in the claims, the term “connected” means a direct connection, such as electrical, mechanical, or magnetic connection between the elements that are connected, without any intermediary devices. The term “coupled” means a direct or indirect connection, such as a direct electrical, mechanical, or magnetic connection between the elements that are connected or an indirect connection, through one or more passive or active intermediary devices.

The description may use perspective-based descriptions such as top/bottom, in/out, over/under, and the like. Such descriptions are merely used to facilitate the discussion and are not intended to restrict the application of embodiments described herein to any particular orientation.

The terms “over,” “under,” “between,” and “on” as used herein refer to a relative position of one component or material with respect to other components or materials where such physical relationships are noteworthy. For example, in the context of materials, one material or layer over or under another may be directly in contact or may have one or more intervening materials or layers. Moreover, one material between two materials or layers may be directly in contact with the two materials/layers or may have one or more intervening materials/layers. In contrast, a first material or layer “on” a second material or layer means that at least a part of the first material or layer is in direct physical contact with at least a part of that second material/layer. Similar distinctions are to be made in the context of component assemblies.

As used herein, “A is adjacent to B” means that at least part of A is in direct physical contact with at least a part of B.

As used herein, “A is proximate to B” may mean that A is adjacent to B or A is otherwise near to B.

Unless otherwise specified in the specific context of use, the term “predominantly” means more than 50%, or more than half. For example, a composition that is predominantly a first constituent means more than half of the composition (e.g., by volume) is the first constituent (e.g., >50 at. %). The term “primarily” means the most, or greatest, part. For example, a composition that is primarily a first constituent means the composition has more of the first constituent (e.g., by volume) than any other constituent. A composition that is primarily first and second constituents means the composition has more of the first and second constituents than any other constituent. The term “substantially” means there is only incidental variation. For example, composition that is substantially a first constituent means the composition may further include <1% of any other constituent. A composition that is substantially first and second constituents means the composition may further include <1% of any constituent substituted for either the first or second constituent.

The terms “substantially,” “close,” “approximately,” “near,” and “about,” generally refer to being within +/−10% of a target value (unless specifically specified).

Unless otherwise specified in the explicit context of their use, the terms “substantially equal,” “about equal” or “approximately equal” mean that there is no more than incidental variation between two things so described. In the art, such variation is typically no more than +/−10% of a predetermined target value.

In the corresponding drawings of the embodiments, signals, currents, electrical biases, or magnetic or electrical polarities may be represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, polarity, current, voltage, etc., as dictated by design needs or preferences, may actually comprise one or more signals that may travel in either direction and may be implemented with any suitable type of signal scheme.

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements.

Although the figures may illustrate embodiments where structures are substantially aligned to Cartesian axes (e.g., device structures having substantially vertical sidewalls), positive and negative (re-entrant) sloped feature sidewalls often occur in practice. For example, manufacturing non-idealities may cause one or more structural features to have sloped sidewalls. Thus, attributes illustrated are idealized merely for the sake of clearly describing salient features. It is to be understood that schematic illustrations may not reflect real-life process limitations which may cause the features to not look so “ideal” when any of the structures described herein are examined using e.g., scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

Example 1 includes an apparatus comprising an integrated circuit device, the integrated circuit device comprising a fiducial area in a first layer of the integrated circuit, the fiducial area comprising at least one metal area and at least one metal free area; and a zone underneath a portion of the at least one metal free area of the fiducial area, the zone having a lateral cross section of a slit through a plurality of layers comprising metal interconnect of the integrated circuit device, the zone allowing infrared (IR) light to pass through the cross section of the plurality of layers.

Example 2 includes the subject matter of Example 1, and wherein the integrated circuit device comprises a plurality of zones underneath portions of the at least one metal free area of the fiducial area, wherein each zone has a lateral cross section of a slit through the plurality of metal layers of the integrated circuit, the zones each allowing infrared IR light to pass through the respective cross section of the plurality of metal layers of the integrated circuit.

Example 3 includes the subject matter of any of Examples 1 and 2, and further including a second integrated circuit device, the second integrated circuit device comprising a second fiducial area in a second layer of the second integrated circuit, the second fiducial area comprising at least one metal area and at least one metal free area, wherein an overlay of the fiducial area over the second fiducial area includes a no-metal area that defines the slits of the zones.

Example 4 includes the subject matter of any of Examples 1-3, and wherein the slits for the lateral cross sections of the zones collectively form a ring.

Example 5 includes the subject matter of any of Examples 1-4, and wherein the ring is a square shaped ring.

Example 6 includes the subject matter of any of Examples 1-5, and wherein a metal area of the at least one metal area has a shape of a solid square.

Example 7 includes the subject matter of any of Examples 1-6, and wherein a second metal area of the at least one metal area has a shape of a square shaped ring.

Example 8 includes the subject matter of any of Examples 1-7, and wherein the zone is metal free.

Example 9 includes the subject matter of any of Examples 1-8, and wherein the apparatus further comprises a printed circuit board attached to the integrated circuit device and second integrated circuit device.

Example 10 includes the subject matter of any of Examples 1-9, wherein the apparatus further comprises a third integrated circuit device coupled to the printed circuit board.

Example 11 includes a system comprising a printed circuit board; and a package coupled to the printed circuit board, the package comprising a first integrated circuit device comprising a fiducial area of a first layer, the fiducial area comprising a metal area and a metal free area; and a plurality of zones that are metal free in multiple layers adjacent to the first layer, wherein the zones are defined by a footprint having a plurality of slits, wherein the footprint is within the metal free area of the fiducial area.

Example 12 includes the subject matter of Example 11, and wherein the package further comprises a second integrated circuit device comprising a second fiducial area of a second layer, the fiducial area comprising a second metal area and a second metal free area, wherein the footprint is based on the metal area of the fiducial area and the second metal area of the second fiducial area.

Example 13 includes the subject matter of any of Examples 11 and 12, and wherein the second integrated circuit device comprises a plurality of second zones that are metal free in multiple layers adjacent to the second layer, wherein the second zones are also defined by the footprint.

Example 14 includes the subject matter of any of Examples 11-13, and wherein the first integrated circuit device is hybrid bonded to the second integrated circuit device.

Example 15 includes the subject matter of any of Examples 11-14, and further including a third integrated circuit device coupled to the printed circuit board.

Example 16 includes the subject matter of any of Examples 11-15, and wherein the plurality of slits collectively form a ring.

Example 17 includes the subject matter of any of Examples 11-16, and wherein the ring is a square shaped ring.

Example 18 includes the subject matter of any of Examples 11-17, and wherein the metal area has a shape of a solid square.

Example 19 includes the subject matter of any of Examples 11-18, wherein the metal area has a shape of a square shaped ring.

Example 20 includes an apparatus comprising an integrated circuit device comprising a fiducial area of a first layer, the fiducial area comprising a metal area and a metal free area; and a plurality of zones that are metal free in multiple layers adjacent to the first layer, wherein the zones are defined by a footprint based on the fiducial area of the first layer and a second fiducial area of a second integrated circuit device, the footprint comprising multiple slits.

Example 21 includes the subject matter of Example 20, and wherein the metal area of the fiducial area and a second metal area of the second fiducial area are concentric.

Example 22 includes the subject matter of any of Examples 20 and 21, and wherein the metal area of the fiducial area has a first solid shape and a second metal area of the fiducial area has a shape of a ring.

Example 23 includes the subject matter of any of Examples 20-22, and further including the second integrated circuit device.

Example 24 includes the subject matter of any of Examples 20-23, and wherein the second integrated circuit device comprises a plurality of zones that are metal free in multiple layers adjacent to a second layer comprising the fiducial area, wherein the zones of the second integrated circuit device are defined by the footprint.

Example 25 includes the subject matter of any of Examples 20-24, and wherein the multiple slits collectively form a ring.

Example 26 includes the subject matter of any of Examples 20-25, and wherein the ring is a square shaped ring.

Example 27 includes the subject matter of any of Examples 20-26, and wherein the metal area has a shape of a solid square.

Example 28 includes the subject matter of any of Examples 20-27, and wherein the metal area has a shape of a square shaped ring.

Example 29 includes a method comprising forming an integrated circuit device comprising a fiducial area of a first layer, the fiducial area comprising a metal area and a metal free area; and forming a plurality of zones that are metal free in multiple layers adjacent to the first layer, wherein the zones are defined by a footprint based on the fiducial area of the first layer and a second fiducial area of a second integrated circuit device, the footprint comprising multiple slits.

Example 30 includes the subject matter of Example 29, and wherein the metal area of the fiducial area and a second metal area of the second fiducial area are concentric.

Example 31 includes the subject matter of any of Examples 29 and 30, and wherein the metal area of the fiducial area has a first solid shape and a second metal area of the fiducial area has a shape of a ring.

Example 32 includes the subject matter of any of Examples 29-31, and further including the second integrated circuit device.

Example 33 includes the subject matter of any of Examples 29-32, and wherein the second integrated circuit device comprises a plurality of zones that are metal free in multiple layers adjacent to a second layer comprising the fiducial area, wherein the zones of the second integrated circuit device are defined by the footprint.

Example 34 includes the subject matter of any of Examples 29-33, and wherein the multiple slits collectively form a ring.

Example 35 includes the subject matter of any of Examples 29-34, and wherein the ring is a square shaped ring.

Example 36 includes the subject matter of any of Examples 29-35, and wherein the metal area has a shape of a solid square.

Example 37 includes the subject matter of any of Examples 29-36, and wherein the metal area has a shape of a square shaped ring.

The foregoing description, for the purpose of explanation, has been described with reference to specific example embodiments. However, the illustrative discussions above are not intended to be exhaustive or to limit the possible example embodiments to the precise forms disclosed. Many modifications and variations are possible in view of the above teachings. The example embodiments were chosen and described in order to best explain the principles involved and their practical applications, to thereby enable others skilled in the art to best utilize the various example embodiments with various modifications as are suited to the particular use contemplated.

1. An apparatus comprising:
an integrated circuit device, the integrated circuit device comprising:
a fiducial area in a first layer of the integrated circuit, the fiducial area comprising at least one metal area and at least one metal free area; and
a zone underneath a portion of the at least one metal free area of the fiducial area, the zone having a lateral cross section of a slit through a plurality of layers comprising metal interconnect of the integrated circuit device, the zone allowing infrared (IR) light to pass through the cross section of the plurality of layers.

2. The apparatus of claim 1, wherein the integrated circuit device comprises a plurality of zones underneath portions of the at least one metal free area of the fiducial area, wherein each zone has a lateral cross section of a slit through the plurality of metal layers of the integrated circuit, the zones each allowing infrared IR light to pass through the respective cross section of the plurality of metal layers of the integrated circuit.

3. The apparatus of claim 2, further comprising a second integrated circuit device, the second integrated circuit device comprising:
a second fiducial area in a second layer of the second integrated circuit, the second fiducial area comprising at least one metal area and at least one metal free area, wherein an overlay of the fiducial area over the second fiducial area includes a no-metal area that defines the slits of the zones.

4. The apparatus of claim 2, wherein the slits for the lateral cross sections of the zones collectively form a ring.

5. The apparatus of claim 4, wherein the ring is a square shaped ring.

6. The apparatus of claim 1, wherein a metal area of the at least one metal area has a shape of a solid square.

7. The apparatus of claim 4, wherein a second metal area of the at least one metal area has a shape of a square shaped ring.

8. The apparatus of claim 1, wherein the zone is metal free.

9. The apparatus of claim 3, the apparatus further comprising a printed circuit board attached to the integrated circuit device and second integrated circuit device.

10. The apparatus of claim 9, further comprising a third integrated circuit device coupled to the printed circuit board.

11. A system comprising:
a printed circuit board; and
a package coupled to the printed circuit board, the package comprising a first integrated circuit device comprising:
a fiducial area of a first layer, the fiducial area comprising a metal area and a metal free area; and
a plurality of zones that are metal free in multiple layers adjacent to the first layer, wherein the zones are defined by a footprint having a plurality of slits, wherein the footprint is within the metal free area of the fiducial area.

12. The system of claim 11, wherein the package further comprises a second integrated circuit device comprising a second fiducial area of a second layer, the fiducial area comprising a second metal area and a second metal free area, wherein the footprint is based on the metal area of the fiducial area and the second metal area of the second fiducial area.

13. The system of claim 12, wherein the second integrated circuit device comprises a plurality of second zones that are metal free in multiple layers adjacent to the second layer, wherein the second zones are also defined by the footprint.

14. The system of claim 12, wherein the first integrated circuit device is hybrid bonded to the second integrated circuit device.

15. The system of claim 12, further comprising a third integrated circuit device coupled to the printed circuit board.

16. An apparatus comprising:
an integrated circuit device comprising a fiducial area of a first layer, the fiducial area comprising a metal area and a metal free area; and
a plurality of zones that are metal free in multiple layers adjacent to the first layer, wherein the zones are defined by a footprint based on the fiducial area of the first layer and a second fiducial area of a second integrated circuit device, the footprint comprising multiple slits.

17. The apparatus of claim 16, wherein the metal area of the fiducial area and a second metal area of the second fiducial area are concentric.

18. The apparatus of claim 16, wherein the metal area of the fiducial area has a first solid shape and a second metal area of the fiducial area has a shape of a ring.

19. The apparatus of claim 16, further comprising the second integrated circuit device.

20. The apparatus of claim 19, wherein the second integrated circuit device comprises a plurality of zones that are metal free in multiple layers adjacent to a second layer comprising the fiducial area, wherein the zones of the second integrated circuit device are defined by the footprint.
